(19) United States
(12) Patent Application Publication
(10) Pub. No.: US 2025/0112540 A1
(43) Pub. Date: Apr. 3, 2025

(54) METHODS AND APPARATUS TO CONTROL SWITCHING CONVERTERS USING PEAK AND VALLEY CONTROL

(71) Applicant: Texas Instruments Incorporated, Dallas, TX (US)

(72) Inventors: Ariel Dario Moctezuma, Richardson, TX (US); Sethu Mathavan Meikandamuthu Ayanar, Bangalore (IN); Nimidev Kovilparambil Prasannan, Bangalore (IN)

(21) Appl. No.: 18/375,214

(22) Filed: Sep. 29, 2023

(51) Int. Cl. H02M 1/00; G01R 31/40; H02M 1/08; H02M 3/156

(52) U.S. Cl. CPC H02M 1/0009; G01R 31/40; H02M 1/08; H02M 3/156

(57) ABSTRACT

An example apparatus includes: error detection circuitry having an input and an output, the error detection circuitry configured to integrate a difference between a voltage of the input of the error detection circuitry and a reference voltage to produce an integrated error voltage; peak controller circuitry coupled to the error detection circuitry, the peak controller circuitry to compare a control current to a first reference current to generate a peak control current, the control current based on an integrated error voltage, the peak control current to increase an output current of converter circuitry; and valley controller circuitry coupled to the error detection circuitry and the peak controller circuitry, the valley controller circuitry to compare the control current to a second reference current to generate a valley control current, the valley control current to decrease the output current of the converter circuitry.

### TECHNICAL FIELD

This description relates generally to switching converter circuitry and, more particularly, to methods and apparatus to control switching converters using peak and valley control.

### BACKGROUND

As electronics continue to advance, circuitry has become capable of performing increasingly complex operations while consuming less power. Some such circuitry relies on converter circuitry that efficiently and accurately supplies relatively small currents with relatively low voltage fixed frequency ripples, and relatively high direct current (DC) accuracy. One common type of converter circuitry is switching converter circuitry that regulates a supply of power to a load using switching operations.

### SUMMARY

For methods and apparatus to control switching converters using peak and valley control, an example apparatus includes error detection circuitry having an input and an output, the error detection circuitry configured to integrate a difference between a voltage of the input of the error detection circuitry and a reference voltage to produce an integrated error voltage; peak controller circuitry coupled to the error detection circuitry, the peak controller circuitry to compare a control current to a first reference current to generate a peak control current, the control current based on an integrated error voltage, the peak control current to increase an output current of converter circuitry; and valley controller circuitry coupled to the error detection circuitry and the peak controller circuitry, the valley controller circuitry to compare the control current to a second reference current to generate a valley control current, the valley control current to decrease the output current of the converter circuitry.

### BRIEF DESCRIPTION OF THE DRAWINGS

FIG. 1 is a block diagram of example switching power converter circuitry that uses example peak-valley controller circuitry to supply power to an example load.

FIG. 2 is a schematic diagram of an example of the peak-valley controller circuitry of FIG. 1 and example non-overlap calibration circuitry having example current controller circuitry to reduce non-overlap between peak and valley control.

FIG. 3 is a block diagram of an example of the current controller circuitry of FIG. 2.

FIG. 4 is a timing diagram of an example operation of the switching power converter circuitry of FIG. 1.

FIG. 5 is a plot of an example operation of the peak-valley controller circuitry of FIGS. 1 and 2.

FIG. 6 is a plot of an example operation of the non-overlap calibration circuitry of FIG. 2 reducing non-overlap between peaks and valleys using the current controller circuitry of FIGS. 2 and 3.

FIG. 7 is a flowchart of example operations that may be performed to implement the peak-valley controller circuitry of FIGS. 1 and 2 and/or more generally the switching power converter circuitry of FIG. 1.

FIG. 8 is a flowchart of example operations that may be performed to implement the switching power converter circuitry of FIG. 1.

FIG. 9 is a flowchart representative of example machine-readable instructions and/or example operations that may be executed, instantiated, and/or performed using an example programmable circuitry implementation of the current controller circuitry of FIGS. 2 and 3.

FIG. 10 is a block diagram of an example processing platform including programmable circuitry structured to execute, instantiate, and/or perform the example machine-readable instructions and/or perform the example operations of FIGS. 7, 8, and/or 9 to implement the current controller circuitry of FIGS. 2 and 3 and/or the switching power supply circuitry of FIG. 1.

FIG. 11 is a block diagram of an example implementation of the programmable circuitry of FIG. 10.

FIG. 12 is a block diagram of another example implementation of the programmable circuitry of FIG. 10.

The same reference numbers or other reference designators are used in the drawings to designate the same or similar (functionally and/or structurally) features.

### DETAILED DESCRIPTION

The drawings are not necessarily to scale. Generally, the same reference numbers in the drawing(s) and this description refer to the same or like parts. The drawings show regions with clean lines and boundaries, some or all of these lines and/or boundaries may be idealized. Moreover, the boundaries and/or lines may be unobservable, blended and/or irregular.

As electronics continue to advance, circuitry has become capable of performing increasingly complex operations while consuming less power. Some such circuitry relies on converter circuitry to efficiently supply relatively small currents. One common type of converter circuitry is switching converter circuitry that regulates a supply of power to a load using switching operations.

Switching operations are based on switching speeds and the mode of operation of the switching converter circuitry. In some devices, switching converter circuitry implements fixed frequency pulse width modulator (PWM) to regulate switching timings. In such devices, fixed frequency PWM utilizes a switching clock signal of a set frequency to regulate timing of switching, which provides a relatively high direct current (DC) accuracy and low ripple on the output. However, current generated using fixed frequency PWM switching converters are limited to magnitudes greater than a minimum current corresponding to a minimum on time of the switching converter. The minimum on time of fixed frequency PWM switching converters is responsive to power consumption of driver circuitry and process limitations. Implementations of fixed frequency PWM switching converter circuitry are limited to applications where the output current is greater than the minimum current.

In some devices, fixed frequency switching converter circuitry is operated in a continuous conduction mode (CCM) to regulate the output. In CCM, the switching converter circuitry controls a supply of current through an inductor such that the magnitude of current through the inductor is greater than zero. Using CCM to regulate outputs of the fixed frequency switching converter circuitry allows for accurate DC regulation. However, CCM switching results in a relatively high-power consumption responsive to maintaining a current through the inductor that is greater than zero.

In other devices, fixed frequency switching converter circuitry is operated in a discontinuous conduction mode (DCM) to regulate the output. In DCM, the switching converter circuitry controls a supply of current through an inductor to generate an output current and voltage. In DCM, the switching converter circuitry allows the magnitude of the current through the inductor to be approximately zero for a duration of a cycle of the switching clock. Using DCM to regulate the output of the fixed frequency switching converter circuitry results in a relatively low power consumption. However, CCM switching has relatively low accuracy DC regulation responsive to allowing the current through the inductor to be approximately zero. For the duration of each cycle of the switching clock signal the fixed frequency switching converter circuitry allows the current through the inductor to be approximately zero.

Examples described herein include methods and apparatus to control converter circuitry for peak and valley control using peak-valley controller circuitry. In some described examples, the peak-valley controller circuitry includes error detection circuitry, peak controller circuitry, and valley controller circuitry. The error detection circuitry compares the output voltage to a reference voltage to determine an integrated error voltage. The peak controller circuitry and the valley controller circuitry generate a control current based on the integrated error voltage. The peak controller circuitry determines a peak threshold of a current through an inductor has been met responsive to a comparison of the control current to a first reference current. The peak controller circuitry generates a peak current to limit the formation of a peak and to begin ramping down current through the inductor.

The valley controller circuitry determines if a valley threshold of a current through the inductor has been met responsive to a comparison of the control current to a second reference current. The valley controller circuitry generates a valley current to limit the formation of a valley and to begin ramping up current through the inductor. The peak-valley controller circuitry allows the current through the inductor to return to approximately zero between valleys of a first cycle of the switching signal and a peak of a second cycle of the switching signal. Advantageously, using the peak-valley controller circuitry to generate a valley following a peak allows switching converter circuitry to accurately supply relatively low currents. Advantageously, the peak-valley controller circuitry improves DC accuracy of switching converter circuitry using DCM operations with fixed frequency PWM.

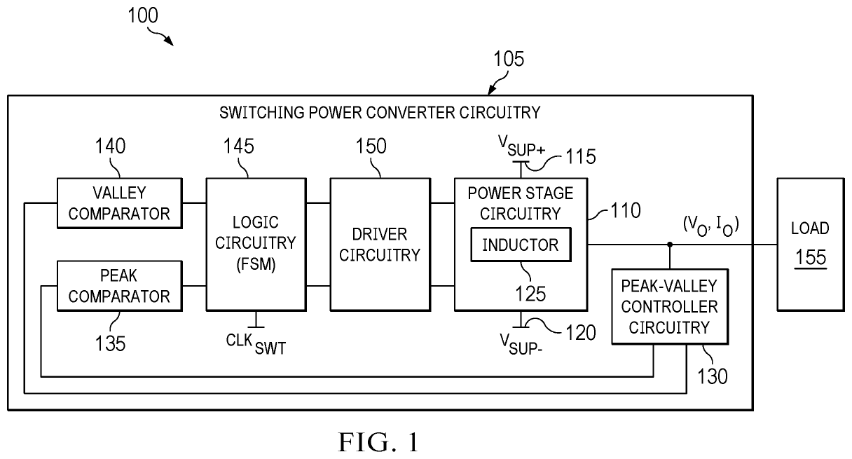

FIG. 1 is a block diagram of an example power supply system 100. In the example of FIG. 1, the power supply system 100 includes example switching power converter circuitry 105, example power stage circuitry 110, a first example supply (V_{SUP+}) 115, a second example supply (V_{SUP-}) 120, an example inductor 125, example peak-valley controller circuitry 130, example peak comparator circuitry 135, example valley comparator circuitry 140, example logic circuitry 145, example driver circuitry 150, and an example load 155. The switching power converter circuitry 105 may supply power to the load 155 responsive to switching controlled by the peak-valley controller circuitry 130.

The switching power converter circuitry 105 is coupled to the load 155. In the example of FIG. 1, the switching power converter circuitry 105 includes the power stage circuitry 110, the supplies 115, 120, the inductor 125, the peak-valley controller circuitry 130, the peak comparator circuitry 135, the valley comparator circuitry 140, the logic circuitry 145, and the driver circuitry 150. The switching power converter circuitry 105 supplies an output voltage (V_{O}) and an output current (I_{O}) to the load 155 responsive to switching operations of the power stage circuitry 110.

The switching power converter circuitry 105 drives current through the inductor 125 using peaks and valleys to control a supply of current. The switching power converter circuitry 105 utilizes valley driving of the inductor 125 to supply a current less than an output current corresponding to minimum peak switching. In some examples, valley driving of the inductor 125 includes operations to allow the current through the inductor 125 to ramp down below zero. In such examples, once the current through the inductor 125 approaches zero, the switching power converter circuitry 105 allows the current to switch directions and begin to ramp up with a negative magnitude. The switching power converter circuitry 105 completes a valley by limiting the ramp up of the current to a value determined by the peak-valley controller circuitry 130. Once limited, the switching power converter circuitry 105 allows the magnitude of the current to decrease to approximately zero. Examples of creating valleys using valley driving are further described below. The minimum peak switching of current through the inductor 125 corresponds to a minimum duration of time that the switching power converter circuitry 105 may use to ramp up current through the inductor 125 while generating a peak. Peak switching includes a plurality of operations to ramp up and ramp down current through the inductor 125. Examples of creating peaks using peak switching are further described below.

In some examples, delays of components of the switching power converter circuitry 105 and/or driving limitations of the inductor 125 determine the minimum peak switching duration. However, the switching power converter circuitry 105 uses valley switching to drive the output current to a value less than the minimum current of the minimum peak switching time. Advantageously, using peak and valley driving, the switching power converter circuitry 105 can supply an output current less than a minimum output current that may be supplied by the minimum peak switching duration. In some examples, the switching power converter circuitry 105 may be a buck converter, a boost converter, a buck-boost converter, etc.

The power stage circuitry 110 has first and second inputs coupled to the driver circuitry 150. The power stage circuitry 110 has a first supply input coupled to the first supply 115 and a second supply input coupled to the second supply 120. The power stage circuitry 110 has an output coupled to the peak-valley controller circuitry 130 and the load 155. In the example of FIG. 1, the power stage circuitry 110 includes the inductor 125 having an inductance (L). The power stage circuitry 110 receives switching signals from the driver circuitry 150. The switching signals from the driver circuitry 150 control the power stage circuitry 110.

The power stage circuitry 110 applies a voltage of one of the supplies 115, 120 across the inductor 125 responsive to the switching signals. The inductor 125 begins to charge in the form of a magnetic field responsive to the voltage from one of the supplies 115, 120. During such example operations, current begins to flow through the inductor 125. In some examples, the power stage circuitry 110 uses one or more transistors, as switches, to be used to couple the supplies 115, 120 to the inductor 125. In such examples, the switching signals may control the one or more transistors. In some examples, the supplies 115, 120 are batteries. In such examples, increasing the power efficiency of the switching power converter circuitry 105 may increase the battery life of the power supply system 100.

In an example operation, a first switching signal from the driver circuitry 150 may be used to couple the first supply 115 to the inductor 125. In such example operations, the first supply 115 charges the magnetic field of the inductor 125 by supplying a current in a first direction. The current through the inductor 125 ramps up responsive to being coupled to the first supply 115. However, when the output current reaches a peak threshold, the first switching signal disconnects the first supply 115 from the inductor 125. The inductor 125 uses energy stored in the magnetic field from the ramp up to continue to cause current to flow through the inductor 125. In such examples, the inductor 125 may supply the current induced by the magnetic field to the load 155. As the inductor 125 discharges, the current through the inductor 125 ramps down. The ramp down of the current through the inductor 125 completes generation of a peak for a cycle of a switching clock (CLK_{SWT}).

In another example operation, when the output current is less than a minimum that may be supplied by just peak switching, a second switching signal from the driver circuitry 150 is used to the current through the inductor 125 below zero. During such operations, the inductor 125 may sink current. In some examples, the second switching signal may be used to couple the inductor 125 to the second supply 120. The current through the inductor 125 continues to ramp down below zero. However, when the output current reaches a valley threshold, the second switching signal disconnects the flow of current through the inductor 125. The inductor 125 uses energy stored in a magnetic field formed during the ramp down below zero to continue to cause current to flow through the inductor 125. In such examples, the inductor 125 may sink current from the load 155 while the magnetic field discharges. As the inductor 125 discharges, the current through the inductor 125 ramps down. The ramp down of the current through the inductor 125 completes generation of a valley for a cycle of the switching clock. The power stage circuitry 110 generates peaks and valleys to supply the output voltage and/or the output current to the peak-valley controller circuitry 130 and the load 155.

The peak-valley controller circuitry 130 has an input coupled to the power stage circuitry 110 and the load 155. The peak-valley controller circuitry 130 has a first output coupled to the peak comparator circuitry 135 and a second output coupled to the valley comparator circuitry 140. The peak-valley controller circuitry 130 receives the output voltage from the power stage circuitry 110.

The peak-valley controller circuitry 130 compares the output voltage to a reference output voltage to determine an error voltage. In the example of FIG. 1, the reference output voltage represents a target output voltage of the switching power converter circuitry 105. In some examples, the reference output voltage may be a scaled version of the target output voltage. In such examples, the peak-valley controller circuitry 130 may include circuitry to scale the output voltage prior to comparing the output voltage to the reference voltage.

The peak-valley controller circuitry 130 determines whether to cause a generation of a peak or valley responsive to the error voltage. In some examples, the peak-valley controller circuitry 130 creates a control current using the error voltage. In such examples, the peak-valley controller circuitry 130 compares the control current to a first reference current and a second reference current.

The peak-valley controller circuitry 130 supplies a peak current (I_{PEAK}) to the peak comparator circuitry 135. When the control current is greater than the first reference current, the peak-valley controller circuitry 130 sets the peak current approximately equal to the control current minus the first reference current. When the control current is less than the first reference current, the peak-valley controller circuitry 130 sets the peak current approximately equal to zero.

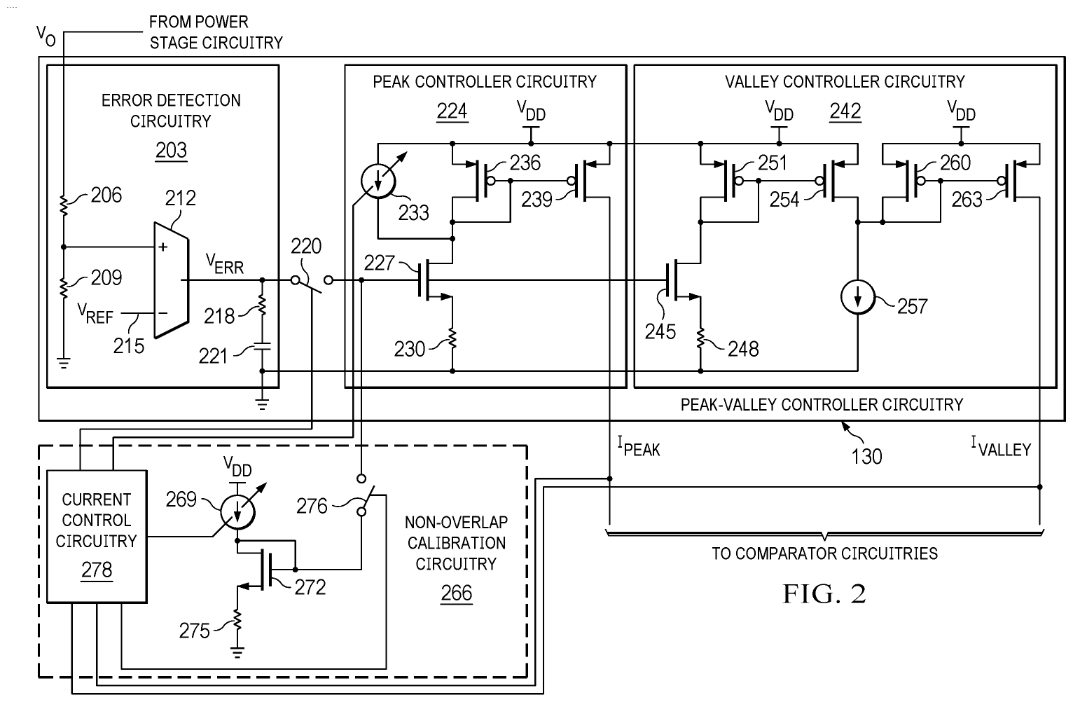

The peak-valley controller circuitry 130 supplies a valley current (I_{VALLEY}) to the valley comparator circuitry 140. When the control current is less than the second reference current, the peak-valley controller circuitry 130 sets the valley current approximately equal to the second reference current minus the control current. When the control current is greater than the second reference current, the peak-valley controller circuitry 130 sets the valley current approximately equal to zero. The peak-valley controller circuitry 130 supplies the peak and/or valley currents to the comparator circuitries 135, 140. An example of the peak-valley controller circuitry 130 is illustrated in FIG. 2, below.

The peak comparator circuitry 135 has an input coupled to the peak-valley controller circuitry 130 and an output coupled to the logic circuitry 145. The peak comparator circuitry 135 receives the peak current from the peak-valley controller circuitry 130. The peak comparator circuitry 135 compares the peak current from the peak-valley controller circuitry 130 to a peak inductor current to generate a peak comparator output. The peak inductor current is a threshold value representative of a target maximum current through the inductor 125 for a peak. In some examples, the peak inductor current is approximately zero such that a minimum peak is generated. In such examples, the output current of the switching power converter circuitry 105 is less than the minimum output current generated by the minimum peak.

When the peak inductor current is greater than or equal to the peak current, the peak comparator circuitry 135 sets the peak comparator output to a logic high (e.g., a logical one). When the peak inductor current is less than the peak current, the peak comparator circuitry 135 sets the peak comparator output to a logic low (e.g., a logical zero). The peak comparator circuitry 135 supplies the peak comparator output to the logic circuitry 145.

The valley comparator circuitry 140 has an input coupled to the peak-valley controller circuitry 130 and an output coupled to the logic circuitry 145. The valley comparator circuitry 140 receives the valley current from the peak-valley controller circuitry 130. The valley comparator circuitry 140 compares the valley current from the peak-valley controller circuitry 130 to a valley inductor current to generate a valley comparator output. The valley inductor current is a threshold value representative of a target minimum current through the inductor 125 for a valley. In some examples, the valley inductor current is determined responsive to the current generated by a minimum peak. In such examples, the output current of the switching power converter circuitry 105 is less than the minimum output current generated by the minimum peak.

When the valley inductor current is less than the valley current, the valley comparator circuitry 140 sets the valley comparator output to a first logic state (e.g., a logical one). When the valley inductor current is greater than the valley current, the valley comparator circuitry 140 sets the valley comparator output to a second logic state (e.g., a logical zero). The valley comparator circuitry 140 supplies the valley comparator output to the logic circuitry 145.

The logic circuitry 145 has inputs coupled to the comparator circuitries 135, 140 and outputs coupled to the driver circuitry 150. The logic circuitry 145 receives the peak comparator output from the peak comparator circuitry 135. The logic circuitry 145 receives the valley comparator output from the valley comparator circuitry 140. The logic circuitry 145 receives and/or includes circuitry to generate a switching clock. The switching clock has a frequency, further having a switching period (T_{SW}), that determines the speed of switching of the switching power converter circuitry 105. The logic circuitry 145 generates reference switching signals responsive to the peak and valley comparator outputs and the switching clock. The logic circuitry 145 supplies the reference switching signals to the driver circuitry 150.

The logic circuitry 145 sets the reference switching signals to a first state responsive to a rising edge of the switching clock. The first state of the reference switching signals corresponds to generation of a peak. The power stage circuitry 110 generates ramps up current through the inductor 125 responsive to the reference switching signals being at the first state. In some examples, the logic circuitry 145 may be referred to as being in a first state and the reference switching signals having a first value responsive to the first state.

The peak comparator output from the peak comparator circuitry 135 is set to a logic high responsive to the peak generated by the first state of the logic circuitry 145. The logic circuitry 145 sets the reference switching signals to a second state responsive to the logic high from the peak comparator circuitry 135. The second state of the reference signals represents the logic circuitry 145 determining an end to the ramp up of the peak started at the rising edge of the switching clock. In such examples, despite the peak inductor current of the peak comparator circuitry 135 being approximately zero, delays between generating the peak and the logic circuitry 145 setting the reference switching signals to the second state result in a minimum peak being generated. The logic circuitry 145 keeps the reference switching signals at the second state to allow the current through the inductor 125 to ramp down.

The valley comparator output from the valley comparator circuitry 140 is set to a logic high responsive to the ramp down started by the transition to the second state by the logic circuitry 145. The logic circuitry 145 sets the reference switching signals to a third state responsive to the logic high of the valley comparator output. The third state of the reference signal represents the logic circuitry 145 determining an end of a ramp down of the current through the inductor 125. The logic circuitry 145 allows the current through the inductor 125 to ramp up to approximately zero following the reference switching signals being the third value.

In some examples, the logic circuitry 145 is a finite state machine (FSM). In such examples, a state of the logic circuitry 145 is determined based on the switching clock and the peak and valley comparator outputs. Alternatively, the logic circuitry 145 may be implemented using programmable circuitry that executes instructions to instantiate the logic circuitry 145.

The driver circuitry 150 has inputs coupled to the logic circuitry 145 and outputs coupled to the power stage circuitry 110. The driver circuitry 150 receives the reference switching signals from the logic circuitry 145. The driver circuitry 150 amplifies the reference switching signals to generate switching signals capable of controlling the power stage circuitry 110. In some examples, the driver circuitry 150 converts a first logic level of the reference switching signals to a second logic level of the power stage circuitry 110. In such examples, the switching signals of the second logic level are capable of switching the power stage circuitry 110. The driver circuitry 150 may be referred to as preamplifier circuitry. The driver circuitry 150 supplies the switching signals to the power stage circuitry 110.

The example load 155 is coupled to the power stage circuitry 110 and the peak-valley controller circuitry 130. The load 155 receives power from the switching power converter circuitry 105. In the example of FIG. 1, the load 155 is external circuitry that consumes power. In some examples, the load 155 may supply a current less than a minimum current achievable by minimum peak switching.

In an example operation, the output current (I_{O}) of the switching power converter circuitry 105 is configurable by the peak current (I_{PEAK}), the valley current (I_{VALLEY}), a duty cycle parameter (K), the switching period (T_{SW}), the first supply voltage (V_{SUP+}), the output voltage (V_{O}), and the inductance (L) of the inductor 125. As described above, the peak and valley currents are outputs of the peak-valley controller circuitry 130. In some examples, the peak and valley currents are determined responsive to the control current and the first and second reference currents of the peak-valley controller circuitry 130. The peak and valley currents are further described below in connection with FIG. 2. The duty cycle parameter is a function of the duty cycle of the peak and valley operations in reference to the switching clock. In the example of FIG. 1, the switching power converter circuitry 105 operating in discontinuous conduction mode (DCM) reduces the duty cycle parameter. The switching period is a period of the switching clock used by the logic circuitry 145. The first supply voltage is the voltage of the first supply 115. The output voltage is the desired output voltage of the switching power converter circuitry 105.

Using Equation (1), below, designers may determine target values of the peak and valley currents to achieve a desired value of the output current. However, in some examples, designers may determine the minimum peak current responsive to the minimum peak.

$${I}_{O} = \frac{\frac{1}{2} * ( {I}_{P E A K}^{2} - {I}_{V A L L E Y}^{2} ) * {K}^{2}}{{T}_{SW} \frac{\vert {V}_{SUP +} - {V}_{O} \vert}{L}} ; \qquad Equation ( 1 )$$

Advantageously, using Equation (1), above, the switching power converter circuitry 105 may supply output current less than a minimum output current of a minimum possible peak. Advantageously, the reference currents of the peak-valley controller circuitry 130 may be set based on the peak and valley currents determined using Equation (1), above. Advantageously, the switching power converter circuitry 105 may implement buck and/or boost operations using Equation (1), above. Although in the example of FIG. 1, Equation (1) is used to determine peak and valley currents of the switching power converter circuitry 105, alternative Equations may be used in accordance with this description. For example, Equation (1) may be modified based on an alternative example implementation of the peak-valley controller circuitry 130 or replaced altogether.

FIG. 2 is a schematic diagram of an example implementation of the peak-valley controller circuitry 130 of FIG. 1. In the example of FIG. 2, the peak-valley controller circuitry 130 includes example error detection circuitry 203, a first example resistor 206, a second example resistor 209, an example error amplifier 212, an example reference voltage 215, a third example resistor 218, a first example switch 220, an example capacitor 221, example peak controller circuitry 224, a first example transistor 227, a fourth example resistor 230, first example current source circuitry 233, a second example transistor 236, a third example transistor 239, example valley controller circuitry 242, a fourth example transistor 245, a fifth example resistor 248, a fifth example transistor 251, a sixth example transistor 254, second example current source circuitry 257, a seventh example transistor 260, and an eighth example transistor 263.

FIG. 2 further includes example non-overlap calibration circuitry 266 coupled to the peak-valley controller circuitry 130. In the example of FIG. 2, the non-overlap calibration circuitry 266 includes third current source circuitry 269, a ninth example transistor 272, a sixth example resistor 275, a second example switch 276, and example current controller circuitry 278.

The error detection circuitry 203 has an input that may be coupled to the power stage circuitry 110 of FIG. 1 and the load 155 of FIG. 1 and an output coupled to the peak controller circuitry 224. In the example of FIG. 2, the error detection circuitry 203 includes the resistors 206, 209, 218, the error amplifier 212, the reference voltage 215, and the capacitor 221. The error detection circuitry 203 receives the output voltage from the power stage circuitry 110. The error detection circuitry 203 compares the output voltage to the reference voltage 215 to determine an integrated error voltage. The integrated error voltage represents the difference between the output voltage and the reference voltage. The error detection circuitry 203 supplies the integrated error voltage to the controller circuitries 224, 242.

The first resistor 206 has a first terminal that may be coupled to the power stage circuitry 110 and the load 155 and a second terminal coupled to the second resistor 209 and the error amplifier 212. The second resistor 209 has a first terminal coupled to the first resistor 206 and the error amplifier 212 and a second terminal coupled to a common terminal that supplies a common potential (e.g., ground). The resistors 206, 209 form resistor divider circuitry. The resistors 206, 209 generate an attenuated output voltage by multiplying the output voltage by an attenuation value (β). In some examples, the resistors 206, 209 stepdown the output voltage responsive to the attenuation value being less than one. In such examples, stepping down the output voltage allows the error detection circuitry 203 to include circuitry of a relatively lower logic level compared to a logic level of the load 155. Advantageously, using relatively lower logic level circuitry for the error detection circuitry 203 decreases cost and increases speed.

The error amplifier 212 has a first input coupled to the resistors 206, 209 and a second input coupled to the reference voltage 215. The error amplifier 212 has an output coupled to the third resistor 218 and the transistors 227, 245 by the first switch 220. The error amplifier 212 receives the attenuated output voltage from the resistors 206, 209. The error amplifier 212 compares the attenuated output voltage to the reference voltage 215. The error amplifier 212 generates an integrated error output proportional to differences between the attenuated output voltage and the reference voltage 215. In some examples, the integrated error output from the error amplifier 212 is a current proportional to the differences between the attenuated output voltage and the reference voltage 215. In such examples, the error amplifier 212 may be referred to as a transconductance circuitry having a transconductance (gₘ). The error amplifier supplies the integrated error output to the third resistor 218.

The reference voltage 215 is coupled to the error amplifier 212. The reference voltage 215 represents a target value of the output voltage. In some examples, the reference voltage 215 is an attenuated version of the target value. In such examples, the reference voltage 215 is approximately equal to the target value of the output voltage times the attenuation value of the resistors 206, 209.

The third resistor 218 has a first terminal coupled to the error amplifier 212 and the transistors 227, 245 by the first switch 220 and a second terminal coupled to the capacitor 221. The capacitor 221 has a first terminal coupled to the third resistor 218 and a second terminal coupled to the common terminal, which supplies the common potential. The third resistor 218 receives the integrated error output from the error amplifier 212. The third resistor 218 and the capacitor 221 generate an integrated error voltage (V_{ERR}) responsive to the integrated error output. In some examples, the capacitor 221 isolates currents of the integrated error output from the common potential. In such examples, the error amplifier 212 may modify the integrated voltage output by sinking and/or sourcing additional current.

The first switch 220 has a first terminal coupled to the error amplifier 212 and the third resistor 218 and a second terminal coupled to the transistors 227, 245 and the second switch 276. The first switch 220 has a control terminal coupled to the current control circuitry 278. The current control circuitry 278 controls the first switch 220. When closed (e.g., conducting), the first switch 220 supplies the integrated error voltage to the transistors 227, 245. When open (e.g., non-conducting), the first switch 220 prevents the integrated error voltage from being supplied to the transistors 227, 245. In some examples, the first switch 220 is a transistor. In the example of FIG. 2, the peak-valley controller circuitry 130 includes the first switch 220. Alternatively, the peak-valley controller circuitry 130 may be modified to directly coupled the error detection circuitry 203 to the controller circuitries 224, 242.

The peak controller circuitry 224 has an input coupled to the error detection circuitry 203 by the first switch 220 and the valley controller circuitry 242. The peak controller circuitry 224 has an output coupled to the non-overlap calibration circuitry 266 and may be coupled to the peak comparator circuitry 135 of FIG. 1. In the example of FIG. 2, the peak controller circuitry 224 includes the transistors 227, 236, 239, the fourth resistor 230, and the first current source circuitry 233. The peak controller circuitry 224 receives the integrated error voltage from the error detection circuitry 203. The peak controller circuitry 224 generates a control current (I_{CTRL}) responsive to the integrated error voltage. The peak controller circuitry 224 compares the control current to a first reference current (I₁). The peak controller circuitry 224 supplies a peak current (I_{PEAK}) to the peak comparator circuitry 135 based on the differences between the first reference current and the control current.

The first transistor 227 has a first terminal coupled to the first current source circuitry 233 and the transistors 236, 239 and a second terminal coupled to the fourth resistor 230. The first transistor 227 has a control terminal coupled to the error amplifier 212, the third resistor 218 by the first switch 220, and the transistors 245, 272 by the second switch 276. The integrated error voltage may control the first transistor 227. The first transistor 227 sources the control current from the first current source circuitry 233 and/or the second transistor 236 responsive to the integrated error voltage. In some examples, the first transistor 227 sources the control current from the first current source circuitry 233. In such examples, the control current is less than the first reference current being supplied by the first current source circuitry 233. In other examples, the first transistor 227 sources the control current from the first current source circuitry 233 and the second transistor 236. In such examples, the control current is greater than the first reference current being supplied by the first current source circuitry 233.

The fourth resistor 230 has a first terminal coupled to the first transistor 227 and a second terminal coupled to the common terminal, which supplies the common potential. The fourth resistor 230 sinks the control current from the first transistor 227. The fourth resistor 230 reduces a voltage difference applied across the transistors 227, 236 and the first current source circuitry 233. In some examples, excessive voltage differences across the transistors 227, 236 and/or the first current source circuitry 233 may result in breaking down and/or tunneling through the transistors 227, 236. Advantageously, the fourth resistor 230 generates a voltage difference capable of reducing the likelihood of damaging the transistors 227, 236 and/or the first current source circuitry 233.

The first current source circuitry 233 has an input coupled to a supply terminal, which supplies a supply voltage (V_{DD}). The first current source circuitry 233 has an output coupled to the transistors 227, 236, 239. The first current source circuitry 233 supplies the first reference current to the first transistor 227. In some examples, the first current source circuitry 233 has a control terminal coupled to the current controller circuitry 278. In such examples, the current controller circuitry 278 may control a magnitude of the first reference current.

The second transistor 236 has a first terminal coupled to the supply terminal, which supplies the supply voltage. The second transistor 236 has a second terminal and a control terminal coupled to the transistors 227, 239 and the first current source circuitry 233. The second transistor 236 is enabled (e.g., conducting) responsive to being forward biased by the control current of the first transistor 227. The control current forward biases the second transistor 236 responsive to being greater than the first reference current from the first current source circuitry 233. The second transistor 236 supplies a current approximately equal to the difference between the control current and the first reference current. However, the second transistor 236 is disabled (e.g., non-conducting) responsive to being reverse biased by the control current of the first transistor 227. The control current reverse biases the second transistor 236 response to being less than the first reference current. In some examples, the configuration of the second transistor 236 may be referred to as a diode configuration.

The third transistor 239 has a first terminal coupled to the supply terminal, which supplied the supply voltage. The third transistor 239 has a second terminal coupled to the current controller circuitry 278 and may be coupled to the peak comparator circuitry 135. The third transistor 239 has a control terminal coupled to the transistors 227, 236 and the first current source circuitry 233. The third transistor 239 sources current from the supply terminal to supply the peak current to the peak comparator circuitry 135. The third transistor 239 mirrors the current flowing through the second transistor 236. For example, the third transistor 239 supplies approximately zero current when the control current of the first transistor 227 reverse biases the second transistor 236. In such examples, the third transistor 239 supplies a current approximately equal to the control current minus the first reference current of the first current source circuitry 233 as the peak current when the control current forward biases the second transistor 236. Advantageously, the peak current of the third transistor 239 is approximately equal to the current flowing through the second transistor 236. In some examples, the circuitry formed by the transistors 236, 239 may be referred to as a current mirror.

The valley controller circuitry 242 has an input coupled to the error detection circuitry 203 and the peak controller circuitry 224. The valley controller circuitry 242 has an output coupled to the non-overlap calibration circuitry 266 and may be coupled to the valley comparator circuitry 140 of FIG. 1. In the example of FIG. 2, the valley controller circuitry 242 includes the transistors 245, 251, 254, 260, 263, the fifth resistor 248, and the second current source circuitry 257. The valley controller circuitry 242 receives the integrated error voltage from the error detection circuitry 203. The valley controller circuitry 242 generates the control current (I_{CTRL}) responsive to the integrated error voltage. The valley controller circuitry 242 compares the control current to a second reference current (I₂). The valley controller circuitry 242 supplies a valley current (I_{VALLEY}) to the valley comparator circuitry 140 based on the differences between the control current and the second reference current.

The fourth transistor 245 has a first terminal coupled to the transistors 251, 254 and a second terminal coupled to the fifth resistor 248. The fourth transistor 245 has a control terminal coupled to the error amplifier 212 and the third resistor 218 by the first switch 220, and the transistors 227, 272 by the second switch 276. The integrated error voltage controls the fourth transistor 245. The fourth transistor 245 sources the control current from the fifth transistor 251 responsive to the integrated error voltage. In some examples, the control current of the fourth transistor 245 is approximately equal to the control current of the first transistor 227.

The fifth resistor 248 has a first terminal coupled to the fourth transistor 245 and a second terminal coupled to the common terminal, which supplies the common potential. The fifth resistor 248 sinks the control current from the fourth transistor 245. The fifth resistor 248 reduces a voltage difference applied across the transistors 245, 251. In some examples, excessive voltage differences across the transistors 245, 251 may result in breaking down and/or tunneling through the transistors 245, 251. Advantageously, the fifth resistor 248 generates a voltage difference capable of reducing the likelihood of damaging the transistors 245, 251.

The fifth transistor 251 has a first terminal coupled to the supply terminal, which supplies the supply voltage. The fifth transistor 251 has a second terminal and a control terminal coupled to the transistors 245, 254. The fifth transistor 251 is enabled (e.g., conducting) responsive to being forward biased by the control current of the fourth transistor 245. A non-zero control current forward biases the fifth transistor 251. For example, the fifth transistor 251 is forward biased responsive to the integrated error voltage being greater than the threshold voltage of the fourth transistor 245. The fifth transistor 251 is disabled (e.g., non-conducting) responsive to being reverse biased by the control current. The control current reverse biases the fifth transistor 251 response to being approximately equal to zero. For example, the integrated error voltage is less than a threshold voltage of the fourth transistor 245. In some examples, the configuration of the fifth transistor 251 may be referred to as a diode configuration.

The sixth transistor 254 has a first terminal coupled to the supply terminal, which supplies the supply voltage. The sixth transistor 254 has a second terminal coupled to the second current source circuitry 257 and the transistors 260, 263. The sixth transistor 254 has a control terminal coupled to the transistors 245, 251. The sixth transistor 254 sources current from the supply terminal to supply current to the second current source circuitry 257. The sixth transistor 254 mirrors the current flowing through the fifth transistor 251. For example, the sixth transistor 254 supplies approximately zero current when the current flowing through the transistors 245, 251 is approximately equal to zero. In such examples, the sixth transistor 254 supplies a current approximately equal to the control current to the second current source circuitry 257. In some examples, the circuitry formed by the transistors 251, 254 may be referred to as a current mirror.

The second current source circuitry 257 has an input coupled to the transistors 254, 260 and an output coupled to the common terminal, which supplies the common potential. The second current source circuitry 257 sources the second reference current from the transistors 254, 260. In some examples, the second current source circuitry 257 sources the second reference current from the sixth transistor 254 responsive to the control current being greater than or equal to the second reference current. In such examples, the second current source circuitry 257 sources the second reference current from both of the transistors 254, 260 responsive to the control current being less than the second reference current. The current being sourced from the seventh transistor 260 is approximately equal to the second reference current minus the control current. In some examples, the second current source circuitry 257 has a control terminal coupled to the current controller circuitry 278. In such examples, the current controller circuitry 278 may control a magnitude of the second reference current.

The seventh transistor 260 has a first terminal coupled to the supply terminal, which supplies the supply voltage. The seventh transistor 260 has a second terminal and a control terminal coupled to the transistors 254, 263 and the second current source circuitry 257. The seventh transistor 260 is enabled (e.g., conducting) responsive to being forward biased by the second reference current of the second current source circuitry 257. The second reference current forward biases the seventh transistor 260 responsive to the control current of the transistors 245, 251, 254 being less than the second reference current. The seventh transistor 260 supplies a current approximately equal to the second reference current minus the control current. However, the seventh transistor 260 is disabled (e.g., non-conducting) responsive to being reverse biased by the second reference current. The second reference current reverse biases the seventh transistor 260 response to being less than the control current. In some examples, the configuration of the seventh transistor 260 may be referred to as a diode configuration.

The eighth transistor 263 has a first terminal coupled to the supply terminal, which supplies the supply voltage. The eighth transistor 263 has a second terminal that may be coupled to the valley comparator circuitry 140. The eighth transistor 263 has a control terminal coupled to the transistors 254, 260 and the second current source circuitry 257. The eighth transistor 263 sources current from the supply terminal to supply the valley current to the valley comparator circuitry 140. The eighth transistor 263 mirrors the current flowing through the seventh transistor 260. For example, the eighth transistor 263 supplies approximately zero current when the second reference current of the second current source circuitry 257 reverse biases the seventh transistor 260. In such examples, the eighth transistor 263 supplies a current approximately equal to the second reference current of the second current source circuitry 257 minus the control current of the transistors 245, 251, 254 as the valley current when the second reference current forward biases the seventh transistor 260. Advantageously, the valley current of the eighth transistor 263 is approximately equal to the current flowing through the seventh transistor 260. In some examples, the circuitry formed by the transistors 260, 263 may be referred to as a current mirror.

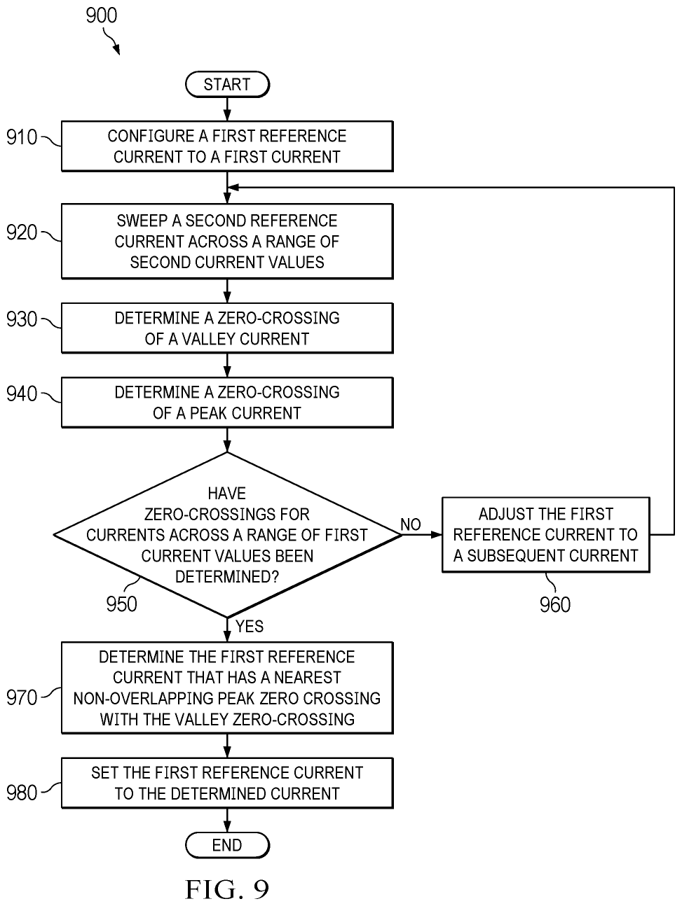

The non-overlap calibration circuitry 266 has inputs coupled to the peak controller circuitry 224 and may be coupled to the comparator circuitries 135, 140. The non-overlap calibration circuitry 266 has outputs coupled to the error detection circuitry 203 and the controller circuitries 224, 242. In the example of FIG. 2, the non-overlap calibration circuitry 266 includes the third current source circuitry 269, the ninth transistor 272, the sixth resistor 275, and the current controller circuitry 278. The non-overlap calibration circuitry 266 calibrates the first reference current of the peak controller circuitry 224 to reduce non-overlapping durations between peaks and valleys. Advantageously, reducing the non-overlapping durations between peaks and valleys increases power efficiency. Example operations of the non-overlap calibration circuitry 266 are further described in connection with FIG. 9, below.

The third current source circuitry 269 has an input coupled to the supply terminal, which supplies the supply voltage, and an output coupled to the ninth transistor 272. The third current source circuitry 269 has a control terminal coupled to the current controller circuitry 278. The third current source circuitry 269 supplies a reference control current to the ninth transistor 272. The current controller circuitry 278 controls the value of the reference control current.

The ninth transistor 272 has a first terminal coupled to the third current source circuitry 269 and a second terminal coupled to the sixth resistor 275. The ninth transistor 272 has a control terminal coupled to the error amplifier 212, the third resistor 218, and the transistors 227, 245. The ninth transistor 272 sources a current approximately equal to the reference control current of the third current source circuitry 269. The ninth transistor 272 generates a reference control voltage responsive to the reference control current. For example, the ninth transistor 272 generates the reference control voltage at the control terminal responsive to the reference control current from the third current source circuitry 269. In some examples, the value of the reference control voltage is configurable by the value of the reference control current. The ninth transistor 272 sets the integrated error voltage approximately equal to the reference control voltage. In some examples, the value of the integrated error voltage induces a control current in the transistors 227, 245 approximately equal to the reference control voltage of the third current source circuitry 269. Advantageously, the ninth transistor 272 sets the control currents of the controller circuitries 224, 242 approximately equal to the third reference control current of the third current source circuitry 269.

The sixth resistor 275 has a first terminal coupled to the ninth transistor 272 and a second terminal coupled to the common terminal, which supplies the common potential. The sixth resistor 275 sinks the reference control current from the ninth transistor 272. The sixth resistor 275 reduces a voltage difference applied across the ninth transistor 272 and the third current source circuitry 269. In some examples, excessive voltage differences across the ninth transistor 272 and/or the third current source circuitry 269 may result in breaking down and/or tunneling through the ninth transistor 272. Advantageously, the sixth resistor 275 generates a voltage difference capable of reducing the likelihood of damaging the ninth transistors 272 and/or the third current source circuitry 269.

The second switch 276 has a first terminal coupled to the first switch 220 and the transistors 227, 245 and a second terminal coupled to the third current source circuitry 269 and the ninth transistor 272. The second switch 276 has a control terminal coupled to the current control circuitry 278. The current control circuitry 278 controls the second switch 276. When closed, the second switch 276 allows the ninth transistor 272 to control the transistors 227, 245. When open, the second switch 276 prevents the ninth transistor 272 from controlling the transistors 227, 245. In some examples, the second switch 276 is a transistor. In the example of FIG. 2, the non-overlap calibration circuitry 266 includes the second switch 276. Alternatively, the non-overlap calibration circuitry 266 may be modified to directly couple the ninth transistor 272 to the transistors 227, 245.

The current controller circuitry 278 has inputs coupled to the transistors 239, 263 and may be coupled to the comparator circuitries 135, 140. The current controller circuitry 278 has a first output coupled to the first current source circuitry 233 and a second output coupled to the third current source circuitry 269. The current controller circuitry 278 receives the peak current from the third transistor 239 and the valley current from the eighth transistor 263. The current controller circuitry 278 controls the first reference current of the first current source circuitry 233 and the reference control current of the third current source circuitry 269. The current controller circuitry 278 calibrates the first reference current to reduce durations of times between peaks and valleys. Such durations of time may be referred to as non-overlapping durations. The current controller circuitry 278 calibrates the first reference current by an improved value that reduces non-overlapping durations.

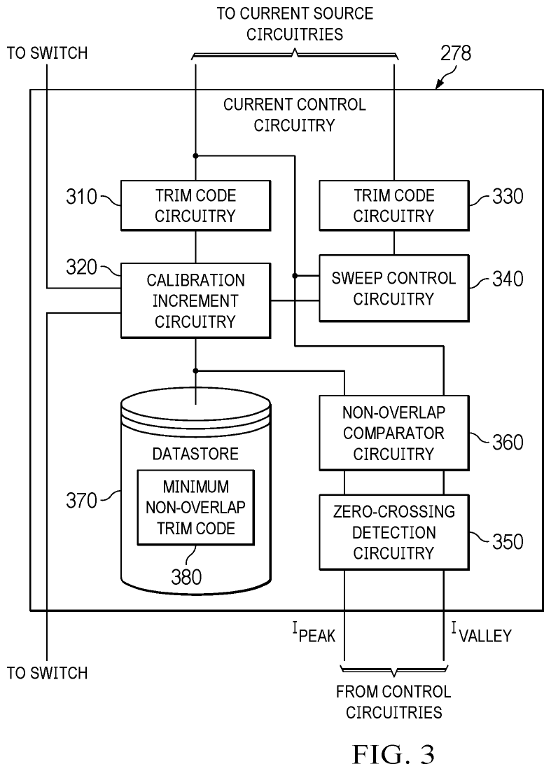

In example operation, the current controller circuitry 278 modifies the first current source circuitry 233 to supply a first value of the first reference current. The current controller circuitry 278 modifies the third current source circuitry 269 to supply a plurality of values of the reference control current. The current controller circuitry 278 determines the reference control currents that correspond to zero crossings of the peak and valley currents. The zero crossings of the peak and valley currents occur at transitions from the peak and/or valley currents from being zero to a finite value or vice versa. In such example operations, the current controller circuitry 278 determines the zero crossings of the peak and/or valley currents for a plurality of values of the first reference current. The current controller circuitry 278 selects the value of the first reference current that reduces the non-overlap between zero crossings of the peak and valley currents. The current controller circuitry 278 configures the first current source circuitry 233 to supply the selected value of the first reference current. Advantageously, the current controller circuitry 278 increases power efficiency of the peak-valley controller circuitry 130 by reducing non-overlap between zero crossings of the peak and valley currents. An example of the current controller circuitry 278 is illustrated in FIG. 3. Example operations of the current controller circuitry 278 are further described in connection with FIGS. 3 and 9, below.

FIG. 3 is a block diagram of an example of the current controller circuitry 278 of FIG. 2. The current controller circuitry 278 of FIG. 3 may be instantiated (e.g., creating an instance of, bring into being for any length of time, materialize, implement, etc.) by programmable circuitry such as a Central Processor Unit (CPU) executing first instructions. Additionally or alternatively, the current controller circuitry 278 of FIG. 3 may be instantiated (e.g., creating an instance of, bring into being for any length of time, materialize, implement, etc.) by (i) an Application Specific Integrated Circuit (ASIC) and/or (ii) a Field Programmable Gate Array (FPGA) structured and/or configured in response to execution of second instructions to perform operations corresponding to the first instructions. It should be understood that some or all of the circuitry of FIG. 3 may, thus, be instantiated at the same or different times. Some or all of the circuitry of FIG. 3 may be instantiated, for example, in one or more threads executing concurrently on hardware and/or in series on hardware. Moreover, in some examples, some or all of the circuitry of FIG. 3 may be implemented by microprocessor circuitry executing instructions and/or FPGA circuitry performing operations to implement one or more virtual machines and/or containers.

The current controller circuitry 278 has inputs that may be coupled to the switches 220, 276 of FIG. 2 and the controller circuitries 224, 242 of FIG. 2. The current controller circuitry 278 has outputs that may be coupled to the peak controller circuitry 224 and the third current source circuitry 269. In the example of FIG. 3, the current controller circuitry 278 includes first example trim code circuitry 310, example calibration increment circuitry 320, second example trim code circuitry 330, example sweep controller circuitry 340, example zero-crossing detection circuitry 350, example non-overlap comparator circuitry 360, an example datastore 370, and an example minimum non-overlap trim code 380. The current controller circuitry 278 receives the peak and valley current from the controller circuitries 224, 242. The current controller circuitry 278 controls the first reference current of the peak controller circuitry 224 and reference control current of the third current source circuitry 269.

The first trim code circuitry 310 has an input coupled to the calibration increment circuitry 320. The first trim code circuitry 310 has an output coupled to the sweep controller circuitry 340 and the non-overlap comparator circuitry 360 and may be coupled to the first current source circuitry 233 of FIG. 2. The first trim code circuitry 310 stores a first trim code. The first trim code configures the first current source circuitry 233 to supply the first reference current. The value of the first reference current is configurable by the first trim code of the first trim code circuitry 310. For example, the first reference current is a first current responsive to the first trim code circuitry 310 having a first value of the first trim code. In such an example, the first reference current is a second current responsive to the first trim code circuitry 310 having a second value of the first trim code. The calibration increment circuitry 320 modifies the first trim code of the first trim code circuitry 310. The first trim code circuitry 310 supplies the first trim code to the sweep controller circuitry 340, the non-overlap comparator circuitry 360, and the first current source circuitry 233. In some examples, the first trim code circuitry 310 is a form of memory. For example, the first trim code circuitry 310 may be a register.

The calibration increment circuitry 320 has a first input coupled to the datastore 370 and a second input coupled to the sweep controller circuitry 340. The calibration increment circuitry 320 has a first output coupled to the first trim code circuitry 310. The calibration increment circuitry 320 has second and third outputs that may be coupled to the switches 220, 276. The calibration increment circuitry 320 begins calibration operations by opening the first switch 220 and closing the second switch 276. The calibration increment circuitry 320 receives a sweep complete indication from the sweep controller circuitry 340. The sweep complete indication indicates whether the sweep controller circuitry 340 is in a process of sweeping the second trim code circuitry 330. In some examples, the sweep controller circuitry 340 sets the sweep complete indication to a first logic state (e.g., logic high, logic low, logical one, logical zero, asserted, not asserted, etc.) while sweeping the second trim code circuitry 330. In such examples, the sweep controller circuitry 340 sets the sweep complete to a second logic state responsive to completing a sweep of the second trim code circuitry 330. The calibration increment circuitry 320 receives the minimum non-overlap trim code 380 from the datastore 370. The calibration increment circuitry 320 sets the first trim code of the first trim code circuitry 310 responsive to the sweep indication and/or the minimum non-overlap trim code 380.

In example operation, the calibration increment circuitry 320 initially sets the first trim code to a first value. The calibration increment circuitry 320 waits for the sweep controller circuitry 340 to complete a sweep operation. In some examples, the calibration increment circuitry 320 determines the sweep controller circuitry 340 has completed a sweep operation responsive to the sweep complete indication transitioning from the first logic state to the second logic state. The calibration increment circuitry 320 sets the first trim code to a second value responsive to the completion of the sweep operation. In some examples, calibration increment circuitry 320 increments or decrements the first trim code to set the first trim code circuitry 310 to the second value. The calibration increment circuitry 320 waits for the sweep controller circuitry 340 to complete another sweep operation responsive to setting the first trim code to the second value.

In such example operations, the calibration increment circuitry 320 continues to increment or decrement the first trim code circuitry 310 across a range of values of the first trim code. In some examples, the range of values of the first trim code are all possible values of the first trim code. In other examples, the range of possible values of the first trim code is a reduced range of all the possible values of the first trim code. When all values of the first trim code in the range of values have been tested, the calibration increment circuitry 320 sets the first trim code of the first trim code circuitry 310 equal to the minimum non-overlapping trim code 380. The calibration increment circuitry 320 completes the calibration operations by closing the first switch 220 and opening the second switch 276. Advantageously, the calibration increment circuitry 320 tests a wide range of possible first reference currents by sweeping the first trim code circuitry 310. In some examples, the calibration increment circuitry 320 is instantiated by programmable circuitry executing calibration increment instructions and/or perform operations such as those represented by the flowchart of FIG. 9.

The second trim code circuitry 330 has an input coupled to the sweep controller circuitry 340. The second trim code circuitry 330 has an output that may be coupled to the third current source circuitry 269. The second trim code circuitry 330 stores a second trim code. The second trim code configures the third current source circuitry 269 to supply the reference control current. The value of the reference control current is configurable by the second trim code of the second trim code circuitry 330. For example, the reference control current is a first current responsive to the second trim code circuitry 310 having a first value of the second trim code. In such an example, the reference control current is a second current responsive to the second trim code circuitry 310 having a second value of the second trim code. The sweep controller circuitry 340 modifies the second trim code of the second trim code circuitry 330. The second trim code circuitry 330 supplies the second trim code to the third current source circuitry 269. In some examples, the second trim code circuitry 330 is a form of memory. For example, the second trim code circuitry 330 may be a register.

The sweep controller circuitry 340 has an input coupled to the first trim code circuitry 310 and the non-overlap comparator circuitry 360. The sweep controller circuitry 340 has a first output coupled to the second trim code circuitry 330 and a second output coupled to the calibration increment circuitry 320. The sweep controller circuitry 340 receives the first trim code from the first trim code circuitry 310. The sweep controller circuitry 340 detects changes to the first trim code. For example, the sweep controller circuitry 340 determines the calibration increment circuitry 320 modified the first trim code circuitry 310 to set the first trim code. The sweep controller circuitry 340 sets the sweep complete indication to a first logic state responsive to determining a change to the first trim code. The sweep controller circuitry 340 performs a sweep operation of the second trim code of the second trim code circuitry 330 responsive to determining the change to the first trim code.

In an example sweep operation, the sweep controller circuitry 340 initially sets the second trim code to a first value. After a delay, the sweep controller circuitry 340 increments or decrements the second trim code circuitry 330 to set the second trim code to a second value. The sweep controller circuitry 340 continues incrementing or decrementing the second trim code circuitry 310 across a range of values of the second trim code. In some examples, the range of values of the second trim code are all possible values of the second trim code. In other examples, the range of possible values of the second trim code is a reduced range of all the possible values of the second trim code. When all values of the second trim code in the range of values have been tested, the sweep controller circuitry 340 sets the sweep complete indication to the second logic state. The second logic state represents a completion of the sweep operations of the sweep controller circuitry 340. In some examples, the sweep controller circuitry 340 is instantiated by programmable circuitry executing sweep control instructions and/or perform operations such as those represented by the flowchart of FIG. 9.

The zero-crossing detection circuitry 350 has first and second inputs coupled to the controller circuitries 224, 242 and first and second outputs coupled to the non-overlap comparator circuitry 360. The zero-crossing detection circuitry 350 receives the peak and valley currents from the controller circuitries 224, 242. The zero-crossing detection circuitry 350 generates a peak zero-crossing indication responsive to the peak current. The zero-crossing detection circuitry 350 sets the peak zero-crossing indication to a first logic state responsive to the peak current being approximately zero. The zero-crossing detection circuitry 350 sets the peak zero-crossing indication to a second logic state responsive to the peak current being non-zero. An edge (e.g., rising or falling edge) of the peak zero-crossing indication represents a zero-crossing of the peak current.

The zero-crossing detection circuitry 350 generates a valley zero-crossing indication responsive to the valley current. The zero-crossing detection circuitry 350 sets the valley zero-crossing indication to a first logic state responsive to the valley current being approximately a zero value. The zero-crossing detection circuitry 350 sets the valley zero-crossing indication to a second logic state responsive to the valley current being a non-zero value. An edge (e.g., rising or falling edge) of the valley zero-crossing indication represents a zero-crossing of the valley current. The zero-crossing detection circuitry 350 supplies the peak and valley zero-crossing indications to the non-overlap comparator circuitry 360. In some examples, the zero-crossing detection circuitry 350 is instantiated by programmable circuitry executing zero-crossing detection instructions and/or perform operations such as those represented by the flowchart of FIG. 9.

The non-overlap comparator circuitry 360 has first and second inputs coupled to the zero-crossing detection circuitry 350 and a third input coupled to the first trim code circuitry 310 and sweep controller circuitry 340. The non-overlap comparator circuitry 360 receives the first trim code from the first trim code circuitry 310. The non-overlap comparator circuitry 360 receives the peak and valley zero-crossing indications from the zero-crossing detection circuitry 350. The non-overlap comparator circuitry 360 determines a non-overlap duration between rising edges of the peak and valley zero-crossing indications for each value of the first trim code. The non-overlap comparator circuitry 360 compares the non-overlap durations of the values of the first trim code to determine a minimum non-overlap duration. The minimum non-overlap duration corresponds to the shortest non-overlap duration without the edges of the zero-crossing indications overlapping. The non-overlap comparator circuitry 360 stores the first trim code corresponding to the minimum non-overlap duration in the datastore 370 as the minimum non-overlap trim code 380. In some examples, the non-overlap comparator circuitry 360 is instantiated by programmable circuitry executing non-overlap comparator instructions and/or perform operations such as those represented by the flowchart of FIG. 9.

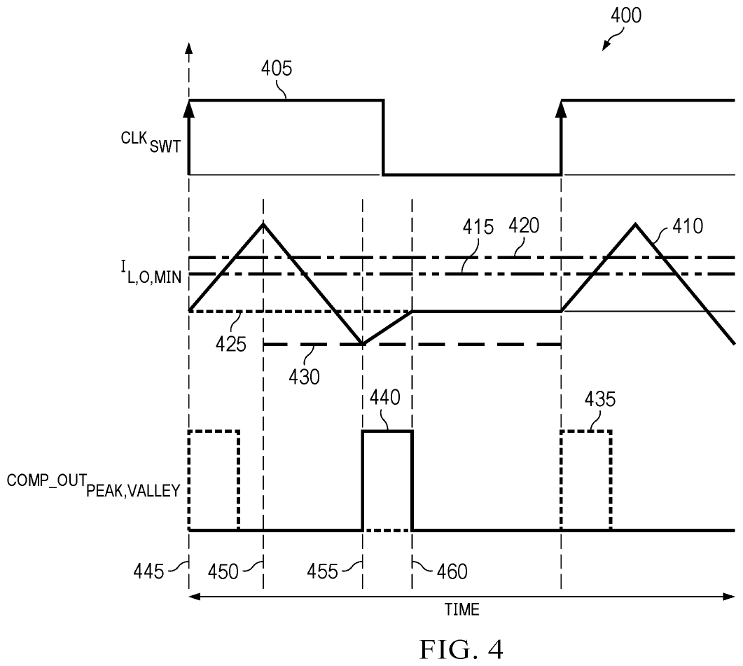

FIG. 4 is a timing diagram 400 of example operations of the switching power converter circuitry 105 of FIG. 1. In the example of FIG. 4, the timing diagram 400 includes an example switching clock (CLK_{SWT}) 405, an example inductor current (I_{L}) 410, an example output current (I_{O}) 415, an example minimum peak current (I_{MIN}) 420, an example peak threshold current 425, an example valley threshold current 430, an example peak comparator output (COMP_OUT_{PEAK}) 435, and an example valley comparator output (COMP_OUTV_{ALLEY}) 440. The timing diagram 400 illustrates example operations of the switching power converter circuitry 105 to supply power to the load 155 of FIG. 1.

The switching clock 405 represents a clock signal that the logic circuitry 145 of FIG. 1 uses to determine when to enter the first state, which initializes a peak. The logic circuitry 145 sets the reference switching signals to the first state responsive to rising edges of the switching clock 405. The frequency of the switching clock 405 may be modified based on the switching capabilities of components of the switching power converter circuitry 105.

The inductor current 410 represents the current flowing through the inductor 125. The output current 415 represents the current being supplied to the load 155 by the switching power converter circuitry 105. The minimum peak current 420 represents a minimum output current of switching converter circuitry while only using peak control. Advantageously, peak and valley control allows the output current 415 to be less than the minimum peak current 420.

The peak threshold current 425 represents the peak inductor current threshold of the peak comparator circuitry 135 of FIG. 1. In the example of FIG. 4, the peak threshold current 425 is approximately equal to zero such that a minimum peak is formed. The valley threshold current 430 represents the valley inductor current threshold of the valley comparator circuitry 140 of FIG. 1. The peak comparator output 435 represents the peak comparator output of the peak comparator circuitry 135. The valley comparator output 440 represents the valley comparator output of the valley comparator circuitry 140.

At a first time 445, the logic circuitry 145 sets the reference switching signals to the first state responsive to a rising edge of the switching clock 405. At the first time 445, the power stage circuitry 110 of FIG. 1 couples the first supply 115 of FIG. 1 across the inductor 125 of FIG. 1 to begin a ramp up of the inductor current 410. At a time immediately following the first time 445, the peak-valley controller circuitry 130 sets the peak current to a non-zero value responsive to the ramp up of the inductor current 410 at the first time 445. The peak comparator circuitry 135 sets the peak comparator output 435 to a logic high to indicate the peak current is greater than the peak threshold current 425.

Between the first time 445 and a second time 450, the logic circuitry 145 sets the reference switching signals to the second state responsive to the peak comparator output 435 being set. At the second time 450, the power stage circuitry 110 removes the first supply 115 from the inductor 125 responsive to the logic circuitry 145 setting the reference switching signals to the second state. The ramp up of the inductor current 410 between the times 445, 450 form a minimum ramp up duration of a minimum peak. The duration between the times 445, 450 is responsive to delays of the circuitry of the switching power converter circuitry 105. At the second time 450, the inductor current 410 begins to ramp down.

At a third time 455, the peak-valley controller circuitry 130 sets the valley current to a non-zero value responsive to the inductor current 410 being approximately equal to the valley threshold current 430. At the third time 455, the valley comparator circuitry 140 sets the valley comparator output 440 to a logic high responsive to the valley current from the peak-valley controller circuitry 130. At approximately the third time 455, the logic circuitry 145 sets the reference switching signals to the third state responsive to the valley comparator output 440. Between the third time 455 and a fourth time 460, the inductor current 410 ramps up. At the fourth time 460, the inductor current 410 is approximately zero.

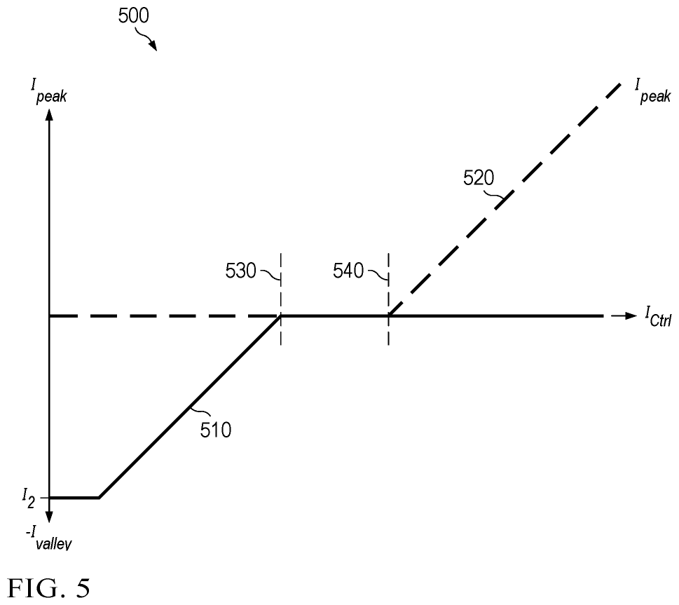

FIG. 5 is a plot 500 of an example operation of the peak-valley controller circuitry 130 of FIGS. 1 and 2. In the example of FIG. 5, the plot 500 includes an example valley current (I_{VALLEY}) 510 and an example peak current (I_{PEAK}) 520. The valley current 510 represents the valley current output of the valley controller circuitry 242 of FIG. 2 across a range of control currents. The peak current 520 represents the peak current output of the peak controller circuitry 224 of FIG. 2 across the range of control currents. The range of control currents represents values of the control current generated by the transistors 227, 245 of FIG. 2 responsive to the integrated error voltage from the error detection circuitry 203 of FIG. 2.

At a first control current 530, the valley current 510 transitions from a non-zero value to approximately a zero value. The current controller circuitry 278 of FIGS. 2 and 3 would determine a zero-crossing of the valley current 510 at approximately the first control current 530. At a second control current 540, the peak current 520 transitions from approximately a zero value to a non-zero value. The current controller circuitry 278 would determine a zero-crossing of the peak current 520 at approximately the second control current 540. Ideally, the zero-crossings of the valley current 510 and the peak current 520 occur at approximately the same control current. However, non-idea conditions (e.g., process variations, component tolerances, etc.) result in a non-overlapping range of control currents. Advantageously, adjusting one or both of the current source circuitries 233, 257 can reduce the range of control currents between the control currents 530, 540.

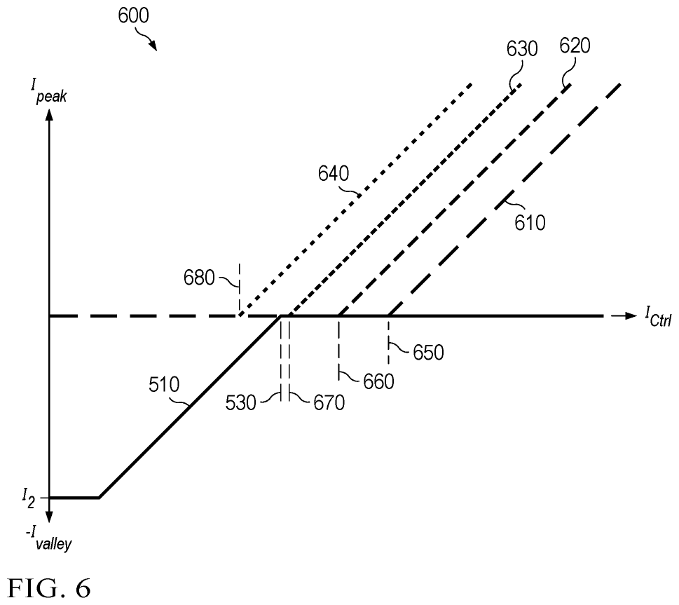

FIG. 6 is a plot 600 of an example operation of the peak-valley controller circuitry 130 of FIGS. 1 and 2. In the example of FIG. 6, the plot 600 includes an example valley current 510 of FIG. 5, the first control current 530 of FIG. 5, a first example peak current 610, a second example peak current 620, a third example peak current 630, and a fourth example peak current 640.

The peak currents 610, 620, 630, 640 represent peak current outputs of the peak controller circuitry 224 of FIG. 2. Each of the peak currents 610, 620, 630, 640 are generated using a different value of the first reference current of the first current source circuitry 233 of FIG. 2. The values of the first reference current are set by the first trim code from the current controller circuitry 278 of FIGS. 2 and 3. In the example of FIG. 6, each of the peak currents 610, 620, 630, 640 are responsive to a different value of the first trim code.

At the first control current 530 of FIG. 5, the valley current 510 transitions from a non-zero value to approximately a zero value. The current controller circuitry 278 determines a zero-crossing of the valley current 510 at approximately the first control current 530. The zero-crossing detection circuitry 350 of FIG. 3 generates an edge responsive to the first control current 530.

At a second control current 650, the first peak current 610 transitions from approximately a zero value to a non-zero value. The current controller circuitry 278 determines a zero-crossing of the first peak current 610 at approximately the second control current 650. The zero-crossing detection circuitry 350 generates an edge responsive to the second control current 650. The non-overlap comparator circuitry 360 of FIG. 3 determines a non-overlap range between the edges at the control currents 530, 650 to be a first range.

At a third control current 660, the second peak current 620 transitions from approximately a zero value to a non-zero value. The current controller circuitry 278 determines a zero-crossing of the second peak current 620 at approximately the third control current 660. The zero-crossing detection circuitry 350 generates an edge responsive to the third control current 660. The non-overlap comparator circuitry 360 determines a non-overlap range between the edges at the control currents 530, 660 to be a second range.

At a fourth control current 670, the third peak current 630 transitions from approximately a zero value to a non-zero value. The current controller circuitry 278 determines a zero-crossing of the third peak current 630 at approximately the fourth control current 670. The zero-crossing detection circuitry 350 generates an edge responsive to the fourth control current 670. The non-overlap comparator circuitry 360 determines a non-overlap range between the edges at the control currents 530, 670 to be a third range.

At a fifth control current 680, the fourth peak current 640 transitions from approximately a zero value to a non-zero value. The current controller circuitry 278 determines a zero-crossing of the fourth peak current 640 at approximately the fifth control current 680. The zero-crossing detection circuitry 350 generates an edge responsive to the fifth control current 680. The non-overlap comparator circuitry 360 determines a non-overlap range between the edges at the control currents 530, 680 to be a fourth range.

The non-overlap comparator circuitry 360 determines that the first trim code may not be the trim code corresponding to the fourth peak current 640 responsive to the fifth control current 680 being less than the first control current 530 of the valley current 510. The non-overlap comparator circuitry 360 compares the first, second, and third ranges to determine the minimum non-overlap trim code 380 of FIG. 3. The non-overlap comparator circuitry 360 determines the third range to be the smallest difference between zero-crossings. The non-overlap comparator circuitry 360 sets the minimum non-overlap trim code 380 equal to the trim code corresponding to the third peak current 630. Advantageously, the current controller circuitry 278 determines a value of the first reference current that reduces non-overlap between the peak and valley currents.

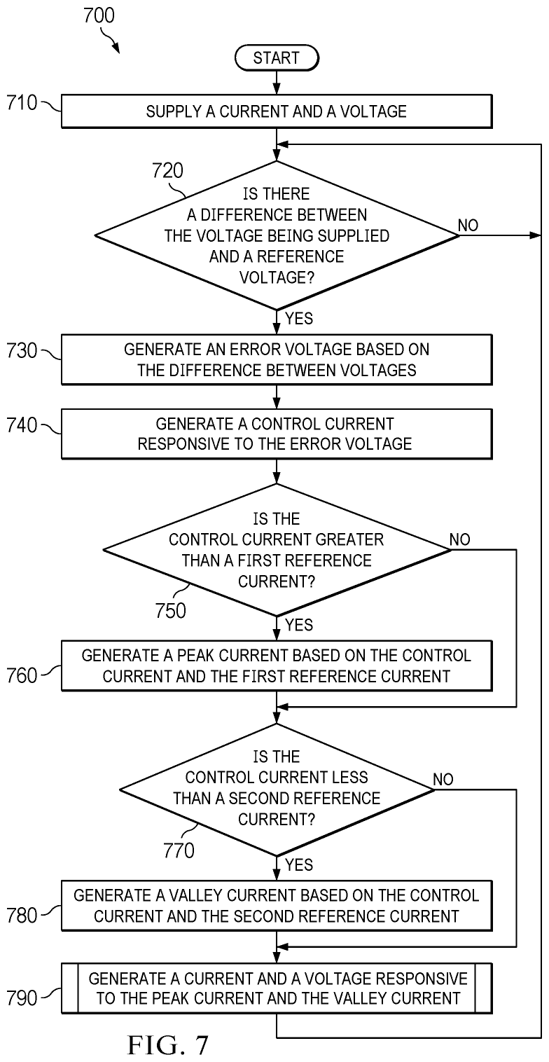

FIG. 7 is a flowchart representative of example operations 700 that may be executed, instantiated, and/or performed to implement the peak-valley controller circuitry 130 of FIGS. 1 and 2 and/or more generally the switching power converter circuitry 105 of FIG. 1. The example operations 700 of FIG. 7 begin at Block 710, where the power stage circuitry 110 of FIG. 1 supplies a current and a voltage. In some examples, the switching power converter circuitry 105 supplies power to the load 155 of FIG. 1 responsive to switching of the power stage circuitry 110. In some examples, the switching power converter circuitry 105 supplies an output current and an output voltage to the load 155.

The error detection circuitry 203 of FIG. 2 determines if there is a difference between the voltage being supplied and a reference voltage. (Block 720). In some examples, the error amplifier 212 of FIG. 2 compares an attenuated version of the output voltage to the reference voltage 215 of FIG. 2. In such examples, the error amplifier 212 generates an output that represents the differences between the output voltage and the reference voltage 215. If the error detection circuitry 203 determines that there is approximately no difference between the voltage being supplied and the reference voltage (e.g., Block 720 returns a result of NO), control proceeds to return to Block 720.

If the error detection circuitry 203 determines that there is a difference between the voltage being supplied and the reference voltage (e.g., Block 720 returns a result of YES), the error detection circuitry 203 generates an error voltage based on the difference between the voltages. (Block 730). In some examples, the error amplifier 212 generates an error voltage proportional to the differences between the attenuated output voltage and the reference voltage 215. In other examples, such as when the error amplifier 212 is transconductance circuitry, the third resistor 218 of FIG. 2 and the capacitor 221 of FIG. 2 generate an integrated error voltage responsive to an error current from the error amplifier 212.

The controller circuitries 224, 242 of FIG. 2 generate a control current responsive to the error voltage. (Block 740). In some examples, the error detection circuitry supplies the integrated error voltage to the transistors 227, 245 of FIG. 2. In such examples, the transistors 227, 245 generate the control current responsive to the integrated error voltage.

The peak controller circuitry 224 determines if the control current is greater than a first reference current. (Block 750). In some examples, the first transistor 227 only sources the control current from the first current source circuitry 233 of FIG. 2 when the first reference current from the first current source circuitry 233 is greater than the control current. In such examples, the first transistor 227 sources the control current from both the first current source circuitry 233 and the second transistor 236 of FIG. 2 when the control current is greater than the first reference current.

If the peak controller circuitry 224 determines the control current is greater than the first reference current (e.g., Block 750 returns a result of YES), the peak controller circuitry 224 generates a peak current based on the control current and the first reference current. (Block 760). In some examples, the first transistor 227 sources the difference between the control current and the first reference current from the second transistor 236. In such examples, the third transistor 239 of FIG. 2 generates the peak current by mirroring the current flowing through the second transistor 236. Control proceeds to Block 770.

If the peak controller circuitry 224 determines the control current is not greater than the first reference current (e.g., Block 750 returns a result of NO), the valley controller circuitry 242 determines if the control current is less than a second reference current. (Block 770). In some examples, the second current source circuitry 257 of FIG. 2 only sources current from the seventh transistor 260 when the control current of the transistors 245, 251, 254 of FIG. 2 is less than the second reference current of the second current source circuitry 257.

If the valley controller circuitry 242 determines that the control current is less than the second reference current (e.g., Block 770 returns a result of YES), the valley controller circuitry 242 generates a valley current based on the control current and the second reference current. (Block 780). In some examples, the second current source circuitry 257 sources the difference between the control current and the second reference current through the seventh transistor 260 responsive to the control current being less than the second reference current. In such examples, the eighth transistor 263 of FIG. 2 generates the valley current by mirroring the current flowing through the seventh transistor 260.

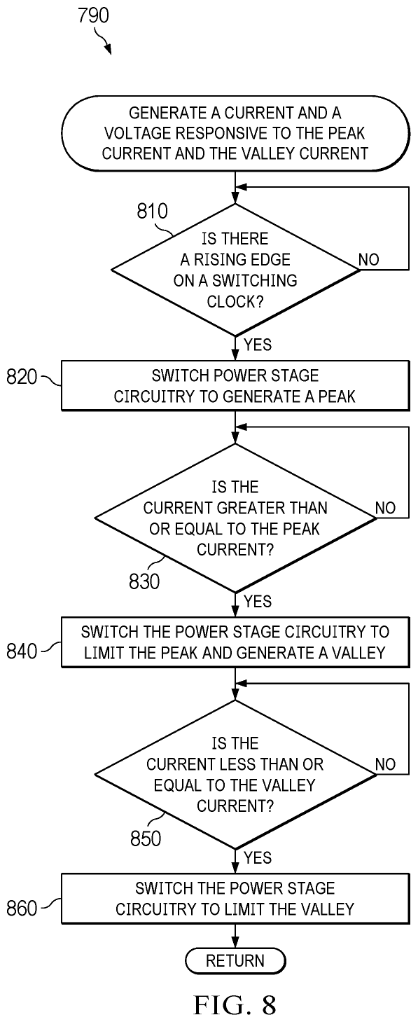

The switching power converter circuitry 105 generates a current and voltage responsive the peak current and the valley current. (Operations 790 of FIG. 8). Control proceeds to return to Block 720.

Although example methods are described with reference to the flowchart illustrated in FIG. 7, many other methods of implementing the peak-valley controller circuitry 130 may alternatively be used in accordance with this description. For example, the order of execution of the blocks may be changed, and/or some of the blocks described may be changed, eliminated, or combined. Similarly, additional operations may be included in the manufacturing process before, in between, or after the blocks shown in the illustrated examples.

FIG. 8 is a flowchart representative of example operations 790 of FIG. 7 that may be executed, instantiated, and/or performed to implement the switching power converter circuitry 105 of FIG. 1. The example operations 790 of FIG. 7 begin at Block 810, where the logic circuitry 145 of FIG. 1 determines if there is a rising edge of a switching clock. (Block 810). In some examples, the switching clock 405 of FIG. 4 is a clock signal that represents the switching frequency of the switching power converter circuitry 105. If the logic circuitry 145 does not detect a rising edge of the switching clock (e.g., Block 810 returns a result of NO), control proceeds to return to Block 810.

If the logic circuitry 145 does detect a rising edge of the switching clock (e.g., Block 810 returns a result of YES), the driver circuitry 150 of FIG. 1 switches the power stage circuitry 110 of FIG. 1 to generate a peak. (Block 820). In some examples, the logic circuitry 145 sets the reference switching signals to a first state responsive to a rising edge of the switching clock 405. In such examples, the driver circuitry 150 generates switching signals to be used to couple the inductor 125 of FIG. 1 to the first supply 115 of FIG. 1 to begin a peak by ramping up current through the inductor 125 responsive to the first state of the reference switching signals.

The peak comparator circuitry 135 of FIG. 1 determines if the current is greater than or equal to the peak current. (Block 830). In some examples, the peak comparator circuitry 135 compares the peak inductor current to the peak current from the peak-valley controller circuitry 130 to determine if the inductor current is greater than a threshold. If the peak comparator circuitry 135 determines the current is not greater than or equal to the peak current (e.g., Block 830 returns a result of NO), control proceeds to return to Block 830.

If the peak comparator circuitry 135 determines the current is greater than or equal to the peak current (e.g., Block 830 returns a result of YES), the driver circuitry 150 switches the power stage circuitry 110 to limit the peak and generate a valley. (Block 840). In some examples, the logic circuitry 145 sets the reference switching signals to the second state responsive to the peak comparator circuitry 135. In such examples, the driver circuitry 150 switches the power stage circuitry 110 to ramp down the current flowing through the inductor 125.

The valley comparator circuitry 140 of FIG. 1 determines if the current is less than or equal to the valley current. (Block 850). In some examples, the valley comparator circuitry 140 compares the valley inductor current to the valley current from the peak-valley controller circuitry 130 to determine if the inductor current is less than a threshold. If the valley comparator circuitry 140 determines the current is not less than or equal to the valley current (e.g., Block 850 returns a result of NO), control proceeds to return to Block 850.

If the valley comparator circuitry 140 determines the current is less than or equal to the valley current (e.g., Block 850 returns a result of YES), the driver circuitry 150 switches the power stage circuitry 110 to limit the valley. (Block 860). In some examples, the logic circuitry 145 sets the reference switching signals to the third state responsive to the valley comparator circuitry 140. In such examples, the driver circuitry 150 switches the power stage circuitry 110 to ramp up the current flowing through the inductor 125. Following the switching at Block 850, the current flowing through the inductor 125 returns to approximately zero. Control proceeds to return.

Although example methods are described with reference to the flowchart illustrated in FIG. 8, many other methods of implementing the switching power converter circuitry 105 may alternatively be used in accordance with this description. For example, the order of execution of the blocks may be changed, and/or some of the blocks described may be changed, eliminated, or combined. Similarly, additional operations may be included in the manufacturing process before, in between, or after the blocks shown in the illustrated examples.

FIG. 9 is a flowchart representative of example operations 900 that may be executed, instantiated, and/or performed to implement the current controller circuitry 278 of FIGS. 2 and 3 and/or more generally non-overlap calibration circuitry 266 of FIG. 2. The example operations 900 of FIG. 9 begin at Block 910, where the first trim code circuitry 310 of FIG. 3 configures a first reference current to a first current. (Block 910). In some examples, the calibration increment circuitry 320 of FIG. 3 sets the first trim code of the first trim code circuitry 310 to an initial value. In such examples, the initial value of the first trim code configures the first current source circuitry 233 of FIG. 2 to supply the first reference current using the first value.

The sweep controller circuitry 340 of FIG. 3 sweeps a second reference current across a range of second reference currents. (Block 920). In some examples, the sweep controller circuitry 340 sets the second trim code circuitry 330 to all possible second trim codes within a range of second trim codes. In such examples, the second trim codes configure the third current source circuitry 269 of FIG. 2 to supply reference control currents across the range of second trim codes.

The zero-crossing detection circuitry 350 of FIG. 3 determines a zero-crossing of a valley current. (Block 930). In some examples, the zero-crossing detection circuitry 350 determines the zero-crossing of the valley current 510 of FIG. 5 responsive to a transition of the valley current 510 from non-zero values to approximately zero. In such examples, the zero-crossing detection circuitry 350 generates an edge to represent the zero-crossing of the valley current.

The zero-crossing detection circuitry 350 determines a zero-crossing of a peak current. (Block 940). In some examples, the zero-crossing detection circuitry 350 determines the zero-crossing of the peak current 520 of FIG. 5 responsive to a transition of the peak current 520 from values approximately equal to zero to non-zero values. In such examples, the zero-crossing detection circuitry 350 generates an edge to represent the zero-crossing of the peak current.

The calibration increment circuitry 320 determines if zero-crossings for current across a range of first current values have been determined. (Block 950). If the calibration increment circuitry 320 determines that not all zero-crossings have been determined for current across a range of first current values (e.g., Block 950 returns a result of NO), the calibration increment circuitry 320 adjusts the first reference current to a subsequent current. (Block 960). In some examples, the calibration increment circuitry 320 continues to increment or decrement the first trim code circuitry 310 across a range of possible first reference currents. In such examples, modifying the first trim code of the first trim code circuitry 310 modifies the first reference current of the first current source circuitry 233.

If the calibration increment circuitry 320 determines that all zero-crossings have been determined for current across a range of first current values (e.g., Block 950 returns a result of YES), the non-overlap comparator circuitry 360 of FIG. 3 determines the first reference current that has a nearest non-overlapping peak zero-crossing with the valley zero-crossing. (Block 970). In some examples, the non-overlap comparator circuitry 360 determines the trim code of the first reference current value that has a zero-crossing nearest to the zero-crossing of the valley current. In such examples, the non-overlap comparator circuitry 360 stores the determined trim code as the minimum non-overlap trim code 380 of FIG. 3.

The calibration increment circuitry 320 sets the first reference current to the determined current. (Block 980). In some examples, the calibration increment circuitry 320 sets the first trim code of the first trim code circuitry 310 equal to the minimum non-overlap trim code 380 responsive to testing all trim codes of the range of first reference trim codes. Control proceeds to End.

Although example methods are described with reference to the flowchart illustrated in FIG. 9, many other methods of implementing the current controller circuitry 278 may alternatively be used in accordance with this description. For example, the order of execution of the blocks may be changed, and/or some of the blocks described may be changed, eliminated, or combined. Similarly, additional operations may be included in the manufacturing process before, in between, or after the blocks shown in the illustrated examples.

While an example manner of implementing the switching power converter circuitry 105 of FIG. 1 is illustrated in FIG. 1 and the current controller circuitry 278 of FIGS. 2 and 3, one or more of the elements, processes, and/or devices illustrated in FIG. 1 and the current controller circuitry 278 of FIGS. 2 and 3 may be combined, divided, re-arranged, omitted, eliminated, and/or implemented in any other way. Further, the comparator circuitries 135, 140 of FIG. 1, the logic circuitry 145 of FIG. 1, the calibration increment circuitry 320 of FIG. 3, the sweep controller circuitry 340 of FIG. 3, the zero-crossing detection circuitry 350 of FIG. 3, the non-overlap comparator circuitry 360 of FIG. 3, and/or, more generally, the example switching power converter circuitry 105 of FIG. 1 and the current controller circuitry 278 of FIGS. 2 and 3, may be implemented by hardware alone or by hardware in combination with software and/or firmware. Thus, for example, any of the comparator circuitries 135, 140 of FIG. 1, the logic circuitry 145 of FIG. 1, the calibration increment circuitry 320 of FIG. 3, the sweep controller circuitry 340 of FIG. 3, the zero-crossing detection circuitry 350 of FIG. 3, the non-overlap comparator circuitry 360 of FIG. 3, and/or, more generally, the example switching power converter circuitry 105, could be implemented by programmable circuitry in combination with machine-readable instructions (e.g., firmware or software), processor circuitry, analog circuit(s), digital circuit(s), logic circuit(s), programmable processor(s), programmable microcontroller(s), graphics processing unit(s) (GPU(s)), digital signal processor(s) (DSP(s)), ASIC(s), programmable logic device(s) (PLD(s)), and/or field programmable logic device(s) (FPLD(s)) such as FPGAs. Further still, the example switching power converter circuitry 105 of FIG. 1 and the current controller circuitry 278 of FIGS. 2 and 3 may include one or more elements, processes, and/or devices in addition to, or instead of, those illustrated in FIG. 1 and the current controller circuitry 278 of FIGS. 2 and 3, and/or may include more than one of any or all of the illustrated elements, processes and devices.

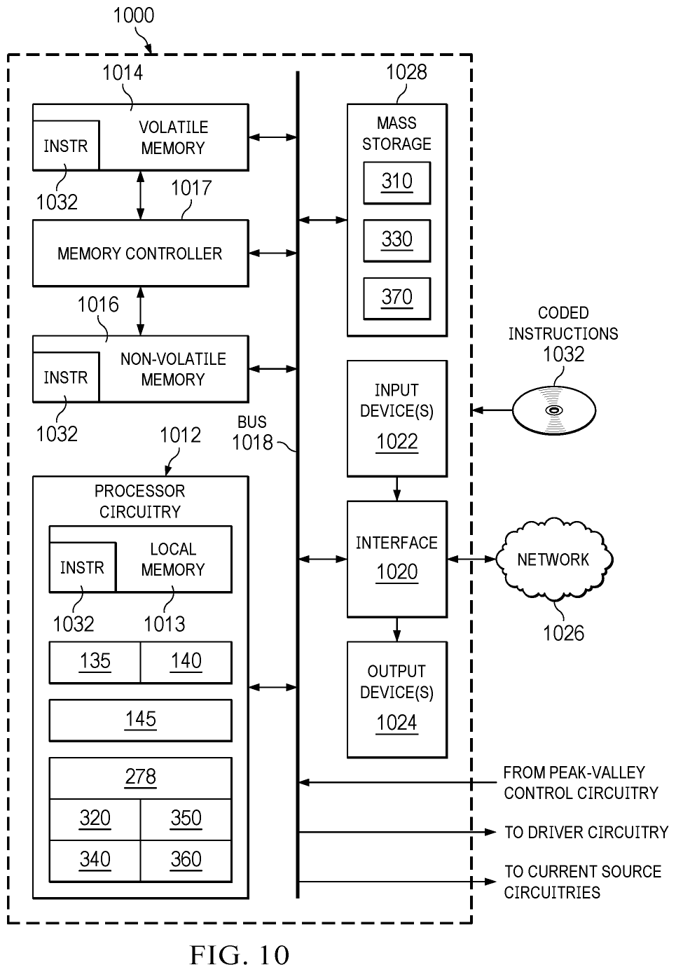

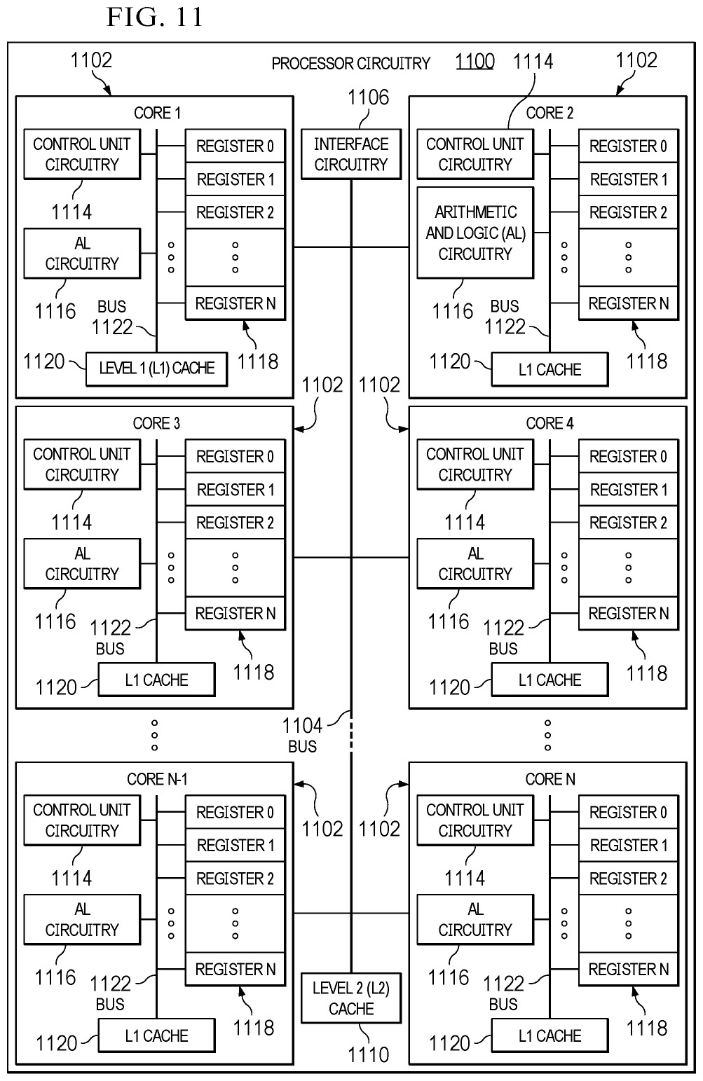

Flowchart(s) representative of example machine-readable instructions, which may be executed by programmable circuitry to implement and/or instantiate the switching power converter circuitry 105 of FIG. 1 and the current controller circuitry 278 of FIGS. 2 and 3 and/or representative of example operations which may be performed by programmable circuitry to implement and/or instantiate the switching power converter circuitry 105 of FIG. 1 and the current controller circuitry 278 of FIGS. 2 and 3, are shown in FIGS. 7, 8, and/or 9. The machine-readable instructions may be one or more executable programs or portion(s) of one or more executable programs for execution by programmable circuitry such as the programmable circuitry 1012 shown in the example programmable circuitry platform 1000 described below in connection with FIG. 10 and/or may be one or more function(s) or portion(s) of functions to be performed by the example programmable circuitry (e.g., an FPGA) described below in connection with FIGS. 11 and/or 12. In some examples, the machine-readable instructions cause an operation, a task, etc., to be carried out and/or performed in an automated manner in the real world. As used herein, “automated” means without human involvement.

The program may be embodied in instructions (e.g., software and/or firmware) stored on one or more non-transitory computer readable and/or machine-readable storage medium such as cache memory, a magnetic-storage device or disk (e.g., a floppy disk, a Hard Disk Drive (HDD), etc.), an optical-storage device or disk (e.g., a Blu-ray disk, a Compact Disk (CD), a Digital Versatile Disk (DVD), etc.), a Redundant Array of Independent Disks (RAID), a register, ROM, a solid-state drive (SSD), SSD memory, non-volatile memory (e.g., electrically erasable programmable read-only memory (EEPROM), flash memory, etc.), volatile memory (e.g., Random Access Memory (RAM) of any type, etc.), and/or any other storage device or storage disk. The instructions of the non-transitory computer readable and/or machine-readable medium may program and/or be executed by programmable circuitry located in one or more hardware devices, but the entire program and/or parts thereof could alternatively be executed and/or instantiated by one or more hardware devices other than the programmable circuitry and/or embodied in dedicated hardware. The machine-readable instructions may be distributed across multiple hardware devices and/or executed by two or more hardware devices (e.g., a server and a client hardware device). For example, the client hardware device may be implemented by an endpoint client hardware device (e.g., a hardware device associated with a human and/or machine user) or an intermediate client hardware device gateway (e.g., a radio access network (RAN)) that may facilitate communication between a server and an endpoint client hardware device. Similarly, the non-transitory computer readable storage medium may include one or more mediums. Further, although the example program is described with reference to the flowchart(s) illustrated in FIGS. 7, 8, and/or 9, many other methods of implementing the example switching power converter circuitry 105 may alternatively be used. For example, the order of execution of the blocks of the flowchart(s) may be changed, and/or some of the blocks described may be changed, eliminated, or combined. Additionally or alternatively, any or all of the blocks of the flow chart may be implemented by one or more hardware circuits (e.g., processor circuitry, discrete and/or integrated analog and/or digital circuitry, an FPGA, an ASIC, a comparator, an operational-amplifier (op-amp), a logic circuit, etc.) structured to perform the corresponding operation without executing software or firmware. The programmable circuitry may be distributed in different network locations and/or local to one or more hardware devices (e.g., a single-core processor (e.g., a single core CPU), a multi-core processor (e.g., a multi-core CPU, an XPU, etc.)). For example, the programmable circuitry may be a CPU and/or an FPGA located in the same package (e.g., the same integrated circuit (IC) package or in two or more separate housings), one or more processors in a single machine, multiple processors distributed across multiple servers of a server rack, multiple processors distributed across one or more server racks, etc., and/or any combination(s) thereof.

The machine-readable instructions described herein may be stored in one or more of a compressed format, an encrypted format, a fragmented format, a compiled format, an executable format, a packaged format, etc. Machine-readable instructions as described herein may be stored as data (e.g., computer-readable data, machine-readable data, one or more bits (e.g., one or more computer-readable bits, one or more machine-readable bits, etc.), a bitstream (e.g., a computer-readable bitstream, a machine-readable bitstream, etc.), etc.) or a data structure (e.g., as portion(s) of instructions, code, representations of code, etc.) that may be utilized to create, manufacture, and/or produce machine executable instructions. For example, the machine-readable instructions may be fragmented and stored on one or more storage devices, disks and/or computing devices (e.g., servers) located at the same or different locations of a network or collection of networks (e.g., in the cloud, in edge devices, etc.). The machine-readable instructions may require one or more of installation, modification, adaptation, updating, combining, supplementing, configuring, decryption, decompression, unpacking, distribution, reassignment, compilation, etc., in order to make them directly readable, interpretable, and/or executable by a computing device and/or other machine. For example, the machine-readable instructions may be stored in multiple parts, which are individually compressed, encrypted, and/or stored on separate computing devices, wherein the parts when decrypted, decompressed, and/or combined form a set of computer-executable and/or machine executable instructions that implement one or more functions and/or operations that may together form a program such as that described herein.

In another example, the machine-readable instructions may be stored in a state in which they may be read by programmable circuitry, but require addition of a library (e.g., a dynamic link library (DLL)), a software development kit (SDK), an application programming interface (API), etc., in order to execute the machine-readable instructions on a particular computing device or other device. In another example, the machine-readable instructions may be configured (e.g., settings stored, data input, network addresses recorded, etc.) before the machine-readable instructions and/or the corresponding program(s) can be executed in whole or in part. Thus, machine-readable, computer readable and/or machine-readable media, as used herein, may include instructions and/or program(s) regardless of the particular format or state of the machine-readable instructions and/or program(s).

The machine-readable instructions described herein can be represented by any past, present, or future instruction language, scripting language, programming language, etc. For example, the machine-readable instructions may be represented using any of the following languages: C, C++, Java, C #, Perl, Python, JavaScript, HyperText Markup Language (HTML), Structured Query Language (SQL), Swift, etc.

As mentioned above, the example operations of FIGS. 7, 8, and/or 9 may be implemented using executable instructions (e.g., computer readable and/or machine-readable instructions) stored on one or more non-transitory computer readable and/or machine-readable media. As used herein, the terms non-transitory computer readable medium, non-transitory computer readable storage medium, non-transitory machine-readable medium, and/or non-transitory machine-readable storage medium are expressly defined to include any type of computer readable storage device and/or storage disk and to exclude propagating signals and to exclude transmission media. Examples of such non-transitory computer readable medium, non-transitory computer readable storage medium, non-transitory machine-readable medium, and/or non-transitory machine-readable storage medium include optical storage devices, magnetic storage devices, an HDD, a flash memory, a read-only memory (ROM), a CD, a DVD, a cache, a RAM of any type, a register, and/or any other storage device or storage disk in which information is stored for any duration (e.g., for extended time periods, permanently, for brief instances, for temporarily buffering, and/or for caching of the information). As used herein, the terms “non-transitory computer readable storage device” and “non-transitory machine-readable storage device” are defined to include any physical (mechanical, magnetic and/or electrical) hardware to retain information for a time period, but to exclude propagating signals and to exclude transmission media. Examples of non-transitory computer readable storage devices and/or non-transitory machine-readable storage devices include random access memory of any type, read only memory of any type, solid state memory, flash memory, optical discs, magnetic disks, disk drives, and/or redundant array of independent disks (RAID) systems. As used herein, the term “device” refers to physical structure such as mechanical and/or electrical equipment, hardware, and/or circuitry that may or may not be configured by computer readable instructions, machine-readable instructions, etc., and/or manufactured to execute computer-readable instructions, machine-readable instructions, etc.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities and/or steps, the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities and/or steps, the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

FIG. 10 is a block diagram of an example programmable circuitry platform 1000 structured to execute and/or instantiate the example machine-readable instructions and/or the example operations of FIGS. 7, 8, and/or 9 to implement the switching power converter circuitry 105 of FIG. 1 and the current controller circuitry 278 of FIGS. 2 and 3. The programmable circuitry platform 1000 can be, for example, a server, a personal computer, a workstation, a self-learning machine (e.g., a neural network), a mobile device (e.g., a cell phone, a smart phone, a tablet such as an iPad™), a personal digital assistant (PDA), an Internet appliance, a DVD player, a CD player, a digital video recorder, a Blu-ray player, a gaming console, a personal video recorder, a set top box, a headset (e.g., an augmented reality (AR) headset, a virtual reality (VR) headset, etc.) or other wearable device, or any other type of computing and/or electronic device.

The programmable circuitry platform 1000 of the illustrated example includes programmable circuitry 1012. The programmable circuitry 1012 of the illustrated example is hardware. For example, the programmable circuitry 1012 can be implemented by one or more integrated circuits, logic circuits, FPGAs, microprocessors, CPUs, GPUs, DSPs, and/or microcontrollers from any desired family or manufacturer. The programmable circuitry 1012 may be implemented by one or more semiconductor based (e.g., silicon based) devices. In this example, the programmable circuitry 1012 implements the comparator circuitries 135, 140 of FIG. 1, the logic circuitry 145 of FIG. 1, the calibration increment circuitry 320 of FIG. 3, the sweep controller circuitry 340 of FIG. 3, the zero-crossing detection circuitry 350 of FIG. 3, the non-overlap comparator circuitry 360 of FIG. 3.

The programmable circuitry 1012 of the illustrated example includes a local memory 1013 (e.g., a cache, registers, etc.). The programmable circuitry 1012 of the illustrated example is in communication with main memory 1014, 1016, which includes a volatile memory 1014 and a non-volatile memory 1016, by a bus 1018. The volatile memory 1014 may be implemented by Synchronous Dynamic Random Access Memory (SDRAM), Dynamic Random Access Memory (DRAM), RAMBUS® Dynamic Random Access Memory (RDRAM®), and/or any other type of RAM device. The non-volatile memory 1016 may be implemented by flash memory and/or any other desired type of memory device. Access to the main memory 1014, 1016 of the illustrated example is controlled by a memory controller 1017. In some examples, the memory controller 1017 may be implemented by one or more integrated circuits, logic circuits, microcontrollers from any desired family or manufacturer, or any other type of circuitry to manage the flow of data going to and from the main memory 1014, 1016.

The programmable circuitry platform 1000 of the illustrated example also includes interface circuitry 1020. The interface circuitry 1020 may be implemented by hardware in accordance with any type of interface standard, such as an Ethernet interface, a universal serial bus (USB) interface, a Bluetooth® interface, a near field communication (NFC) interface, a Peripheral Component Interconnect (PCI) interface, and/or a Peripheral Component Interconnect Express (PCIe) interface.

In the illustrated example, one or more input devices 1022 are connected to the interface circuitry 1020. The input device(s) 1022 permit(s) a user (e.g., a human user, a machine user, etc.) to enter data and/or commands into the programmable circuitry 1012. The input device(s) 1022 can be implemented by, for example, an audio sensor, a microphone, a camera (still or video), a keyboard, a button, a mouse, a touchscreen, a trackpad, a trackball, an isopoint device, and/or a voice recognition system.

One or more output devices 1024 are also connected to the interface circuitry 1020 of the illustrated example. The output device(s) 1024 can be implemented, for example, by display devices (e.g., a light emitting diode (LED), an organic light emitting diode (OLED), a liquid crystal display (LCD), a cathode ray tube (CRT) display, an in-place switching (IPS) display, a touchscreen, etc.), a tactile output device, a printer, and/or speaker. The interface circuitry 1020 of the illustrated example, thus, typically includes a graphics driver card, a graphics driver chip, and/or graphics processor circuitry such as a GPU.

The interface circuitry 1020 of the illustrated example also includes a communication device such as a transmitter, a receiver, a transceiver, a modem, a residential gateway, a wireless access point, and/or a network interface to facilitate exchange of data with external machines (e.g., computing devices of any kind) by a network 1026. The communication can be by, for example, an Ethernet connection, a digital subscriber line (DSL) connection, a telephone line connection, a coaxial cable system, a satellite system, a beyond-line-of-sight wireless system, a line-of-sight wireless system, a cellular telephone system, an optical connection, etc.

The programmable circuitry platform 1000 of the illustrated example also includes one or more mass storage discs or devices 1028 to store firmware, software, and/or data. Examples of such mass storage discs or devices 1028 include magnetic storage devices (e.g., floppy disk, drives, HDDs, etc.), optical storage devices (e.g., Blu-ray disks, CDs, DVDs, etc.), RAID systems, and/or solid-state storage discs or devices such as flash memory devices and/or SSDs.

The machine-readable instructions 1032, which may be implemented by the machine-readable instructions of FIGS. 7, 8, and/or 9, may be stored in the mass storage device 1028, in the volatile memory 1014, in the non-volatile memory 1016, and/or on at least one non-transitory computer readable storage medium such as a CD or DVD which may be removable.

FIG. 11 is a block diagram of an example implementation of the programmable circuitry 1012 of FIG. 10. In this example, the programmable circuitry 1012 of FIG. 10 is implemented by a microprocessor 1100. For example, the microprocessor 1100 may be a general-purpose microprocessor (e.g., general-purpose microprocessor circuitry). The microprocessor 1100 executes some or all of the machine-readable instructions of the flowcharts of FIGS. 7, 8, and/or 9 to effectively instantiate the circuitry of FIG. 2 as logic circuits to perform operations corresponding to those machine-readable instructions. In some such examples, the circuitry of FIG. 1 and the current controller circuitry 278 of FIGS. 2 and 3 is instantiated by the hardware circuits of the microprocessor 1100 in combination with the machine-readable instructions. For example, the microprocessor 1100 may be implemented by multi-core hardware circuitry such as a CPU, a DSP, a GPU, an XPU, etc. Although it may include any number of example cores 1102 (e.g., 1 core), the microprocessor 1100 of this example is a multi-core semiconductor device including N cores. The cores 1102 of the microprocessor 1100 may operate independently or may cooperate to execute machine-readable instructions. For example, machine code corresponding to a firmware program, an embedded software program, or a software program may be executed by one of the cores 1102 or may be executed by multiple ones of the cores 1102 at the same or different times. In some examples, the machine code corresponding to the firmware program, the embedded software program, or the software program is split into threads and executed in parallel by two or more of the cores 1102. The software program may correspond to a portion or all of the machine-readable instructions and/or operations represented by the flowcharts of FIGS. 7, 8, and/or 9.

The cores 1102 may communicate by a first example bus 1104. In some examples, the first bus 1104 may be implemented by a communication bus to effectuate communication associated with one(s) of the cores 1102. For example, the first bus 1104 may be implemented by at least one of an Inter-Integrated Circuit (I2C) bus, a Serial Peripheral Interface (SPI) bus, a PCI bus, or a PCIe bus. Additionally or alternatively, the first bus 1104 may be implemented by any other type of computing or electrical bus. The cores 1102 may obtain data, instructions, and/or signals from one or more external devices by example interface circuitry 1106. The cores 1102 may output data, instructions, and/or signals to the one or more external devices by the interface circuitry 1106. Although the cores 1102 of this example include example local memory 1120 (e.g., Level 1 (L1) cache that may be split into an L1 data cache and an L1 instruction cache), the microprocessor 1100 also includes example shared memory 1110 that may be shared by the cores (e.g., Level 2 (L2 cache)) for high-speed access to data and/or instructions. Data and/or instructions may be transferred (e.g., shared) by writing to and/or reading from the shared memory 1110. The local memory 1120 of each of the cores 1102 and the shared memory 1110 may be part of a hierarchy of storage devices including multiple levels of cache memory and the main memory (e.g., the main memory 1014, 1016 of FIG. 10). Typically, higher levels of memory in the hierarchy exhibit lower access time and have smaller storage capacity than lower levels of memory. Changes in the various levels of the cache hierarchy are managed (e.g., coordinated) by a cache coherency policy.

Each core 1102 may be referred to as a CPU, DSP, GPU, etc., or any other type of hardware circuitry. Each core 1102 includes control unit circuitry 1114, arithmetic and logic (AL) circuitry (sometimes referred to as an ALU) 1116, a plurality of registers 1118, the local memory 1120, and a second example bus 1122. Other structures may be present. For example, each core 1102 may include vector unit circuitry, single instruction multiple data (SIMD) unit circuitry, load/store unit (LSU) circuitry, branch/jump unit circuitry, floating-point unit (FPU) circuitry, etc. The control unit circuitry 1114 includes semiconductor-based circuits structured to control (e.g., coordinate) data movement within the corresponding core 1102. The AL circuitry 1116 includes semiconductor-based circuits structured to perform one or more mathematic and/or logic operations on the data within the corresponding core 1102. The AL circuitry 1116 of some examples performs integer-based operations. In other examples, the AL circuitry 1116 also performs floating-point operations. In yet other examples, the AL circuitry 1116 may include first AL circuitry that performs integer-based operations and second AL circuitry that performs floating-point operations. In some examples, the AL circuitry 1116 may be referred to as an Arithmetic Logic Unit (ALU).

The registers 1118 are semiconductor-based structures to store data and/or instructions such as results of one or more of the operations performed by the AL circuitry 1116 of the corresponding core 1102. For example, the registers 1118 may include vector register(s), SIMD register(s), general-purpose register(s), flag register(s), segment register(s), machine-specific register(s), instruction pointer register(s), control register(s), debug register(s), memory management register(s), machine check register(s), etc. The registers 1118 may be arranged in a bank as shown in FIG. 11. Alternatively, the registers 1118 may be organized in any other arrangement, format, or structure, such as by being distributed throughout the core 1102 to shorten access time. The second bus 1122 may be implemented by at least one of an I2C bus, a SPI bus, a PCI bus, or a PCIe bus.

Each core 1102 and/or, more generally, the microprocessor 1100 may include additional and/or alternate structures to those shown and described above. For example, one or more clock circuits, one or more power supplies, one or more power gates, one or more cache home agents (CHAs), one or more converged/common mesh stops (CMSs), one or more shifters (e.g., barrel shifter(s)) and/or other circuitry may be present. The microprocessor 1100 is a semiconductor device fabricated to include many transistors interconnected to implement the structures described above in one or more integrated circuits (ICs) contained in one or more packages.

The microprocessor 1100 may include and/or cooperate with one or more accelerators (e.g., acceleration circuitry, hardware accelerators, etc.). In some examples, accelerators are implemented by logic circuitry to perform certain tasks more quickly and/or efficiently than can be done by a general-purpose processor. Examples of accelerators include ASICs and FPGAs such as those described herein. A GPU, DSP and/or other programmable device can also be an accelerator. Accelerators may be on-board the microprocessor 1100, in the same chip package as the microprocessor 1100 and/or in one or more separate packages from the microprocessor 1100.

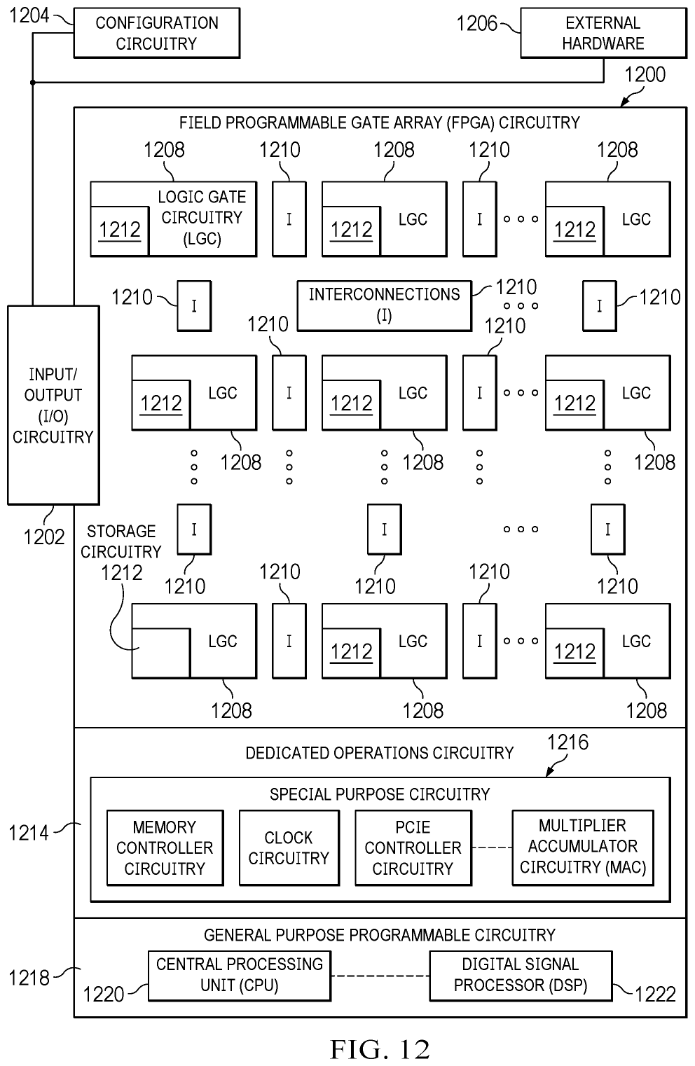

FIG. 12 is a block diagram of another example implementation of the programmable circuitry 1012 of FIG. 10. In this example, the programmable circuitry 1012 is implemented by FPGA circuitry 1200. For example, the FPGA circuitry 1200 may be implemented by an FPGA. The FPGA circuitry 1200 can be used, for example, to perform operations that could otherwise be performed by the example microprocessor 1100 of FIG. 11 executing corresponding machine-readable instructions. However, once configured, the FPGA circuitry 1200 instantiates the operations and/or functions corresponding to the machine-readable instructions in hardware and, thus, can often execute the operations/functions faster than they could be performed by a general-purpose microprocessor executing the corresponding software.

More specifically, in contrast to the microprocessor 1100 of FIG. 11 described above (which is a general purpose device that may be programmed to execute some or all of the machine-readable instructions represented by the flowchart(s) of FIGS. 7, 8, and/or 9 but whose interconnections and logic circuitry are fixed once fabricated), the FPGA circuitry 1200 of the example of FIG. 12 includes interconnections and logic circuitry that may be configured, structured, programmed, and/or interconnected in different ways after fabrication to instantiate, for example, some or all of the operations/functions corresponding to the machine-readable instructions represented by the flowchart(s) of FIGS. 7, 8, and/or 9. In particular, the FPGA circuitry 1200 may be thought of as an array of logic gates, interconnections, and switches. The switches can be programmed to change how the logic gates are interconnected by the interconnections, effectively forming one or more dedicated logic circuits (unless and until the FPGA circuitry 1200 is reprogrammed). The configured logic circuits enable the logic gates to cooperate in different ways to perform different operations on data received by input circuitry. Those operations may correspond to some or all of the instructions (e.g., the software and/or firmware) represented by the flowchart(s) of FIGS. 7, 8, and/or 9. As such, the FPGA circuitry 1200 may be configured and/or structured to effectively instantiate some or all of the operations/functions corresponding to the machine-readable instructions of the flowchart(s) of FIGS. 7, 8, and/or 9 as dedicated logic circuits to perform the operations/functions corresponding to those software instructions in a dedicated manner analogous to an ASIC. Therefore, the FPGA circuitry 1200 may perform the operations/functions corresponding to the some or all of the machine-readable instructions of FIGS. 7, 8, and/or 9 faster than the general-purpose microprocessor can execute the same.

In the example of FIG. 12, the FPGA circuitry 1200 is configured and/or structured in response to being programmed (and/or reprogrammed one or more times) based on a binary file. In some examples, the binary file may be compiled and/or generated based on instructions in a hardware description language (HDL) such as Lucid, Very High-Speed Integrated Circuits (VHSIC) Hardware Description Language (VHDL), or Verilog. For example, a user (e.g., a human user, a machine user, etc.) may write code or a program corresponding to one or more operations/functions in an HDL; the code/program may be translated into a low-level language; and the code/program (e.g., the code/program in the low-level language) may be converted (e.g., by a compiler, a software application, etc.) into the binary file. In some examples, the FPGA circuitry 1200 of FIG. 12 may access and/or load the binary file to cause the FPGA circuitry 1200 of FIG. 12 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1200 of FIG. 12 to cause configuration and/or structuring of the FPGA circuitry 1200 of FIG. 12, or portion(s) thereof.

In some examples, the binary file is compiled, generated, transformed, and/or otherwise output from a uniform software platform utilized to program FPGAs. For example, the uniform software platform may translate first instructions (e.g., code or a program) that correspond to one or more operations/functions in a high-level language (e.g., C, C++, Python, etc.) into second instructions that correspond to the one or more operations/functions in an HDL. In some such examples, the binary file is compiled, generated, and/or otherwise output from the uniform software platform based on the second instructions. In some examples, the FPGA circuitry 1200 of FIG. 12 may access and/or load the binary file to cause the FPGA circuitry 1200 of FIG. 12 to be configured and/or structured to perform the one or more operations/functions. For example, the binary file may be implemented by a bit stream (e.g., one or more computer-readable bits, one or more machine-readable bits, etc.), data (e.g., computer-readable data, machine-readable data, etc.), and/or machine-readable instructions accessible to the FPGA circuitry 1200 of FIG. 12 to cause configuration and/or structuring of the FPGA circuitry 1200 of FIG. 12, or portion(s) thereof.

The FPGA circuitry 1200 of FIG. 12, includes example input/output (I/O) circuitry 1202 to obtain and/or output data to/from example configuration circuitry 1204 and/or external hardware 1206. For example, the configuration circuitry 1204 may be implemented by interface circuitry that may obtain a binary file, which may be implemented by a bit stream, data, and/or machine-readable instructions, to configure the FPGA circuitry 1200, or portion(s) thereof. In some such examples, the configuration circuitry 1204 may obtain the binary file from a user, a machine (e.g., hardware circuitry (e.g., programmable or dedicated circuitry) that may implement an Artificial Intelligence/Machine Learning (AI/ML) model to generate the binary file), etc., and/or any combination(s) thereof). In some examples, the external hardware 1206 may be implemented by external hardware circuitry. For example, the external hardware 1206 may be implemented by the microprocessor 1100 of FIG. 11.

The FPGA circuitry 1200 also includes an array of example logic gate circuitry 1208, a plurality of example configurable interconnections 1210, and example storage circuitry 1212. The logic gate circuitry 1208 and the configurable interconnections 1210 are configurable to instantiate one or more operations/functions that may correspond to at least some of the machine-readable instructions of FIGS. 7, 8, and/or 9 and/or other desired operations. The logic gate circuitry 1208 shown in FIG. 12 is fabricated in blocks or groups. Each block includes semiconductor-based electrical structures that may be configured into logic circuits. In some examples, the electrical structures include logic gates (e.g., And gates, Or gates, Nor gates, etc.) that provide basic building blocks for logic circuits. Electrically controllable switches (e.g., transistors) are present within each of the logic gate circuitry 1208 to enable configuration of the electrical structures and/or the logic gates to form circuits to perform desired operations/functions. The logic gate circuitry 1208 may include other electrical structures such as look-up tables (LUTs), registers (e.g., flip-flops or latches), multiplexers, etc.

The configurable interconnections 1210 of the illustrated example are conductive pathways, traces, vias, or the like that may include electrically controllable switches (e.g., transistors) whose state can be changed by programming (e.g., using an HDL instruction language) to activate or deactivate one or more connections between one or more of the logic gate circuitry 1208 to program desired logic circuits.

The storage circuitry 1212 of the illustrated example is structured to store result(s) of the one or more of the operations performed by corresponding logic gates. The storage circuitry 1212 may be implemented by registers or the like. In the illustrated example, the storage circuitry 1212 is distributed amongst the logic gate circuitry 1208 to facilitate access and increase execution speed.

The example FPGA circuitry 1200 of FIG. 12 also includes example dedicated operations circuitry 1214. In this example, the dedicated operations circuitry 1214 includes special purpose circuitry 1216 that may be invoked to implement commonly used functions to avoid the need to program those functions in the field. Examples of such special purpose circuitry 1216 include memory (e.g., DRAM) controller circuitry, PCIe controller circuitry, clock circuitry, transceiver circuitry, memory, and multiplier-accumulator circuitry. Other types of special purpose circuitry may be present. In some examples, the FPGA circuitry 1200 may also include example general purpose programmable circuitry 1218 such as an example CPU 1220 and/or an example DSP 1222. Other general purpose programmable circuitry 1218 may additionally or alternatively be present such as a GPU, an XPU, etc., that can be programmed to perform other operations.

Although FIGS. 11 and 12 illustrate two example implementations of the programmable circuitry 1012 of FIG. 10, many other approaches are contemplated. For example, FPGA circuitry may include an on-board CPU, such as one or more of the example CPU 1220 of FIG. 11. Therefore, the programmable circuitry 1012 of FIG. 10 may additionally be implemented by combining at least the example microprocessor 1100 of FIG. 11 and the example FPGA circuitry 1200 of FIG. 12. In some such hybrid examples, one or more cores 1102 of FIG. 11 may execute a first portion of the machine-readable instructions represented by the flowchart(s) of FIGS. 7, 8, and/or 9 to perform first operation(s)/function(s), the FPGA circuitry 1200 of FIG. 12 may be configured and/or structured to perform second operation(s)/function(s) corresponding to a second portion of the machine-readable instructions represented by the flowcharts of FIGS. 7, 8, and/or 9, and/or an ASIC may be configured and/or structured to perform third operation(s)/function(s) corresponding to a third portion of the machine-readable instructions represented by the flowcharts of FIGS. 7, 8, and/or 9.

It should be understood that some or all of the circuitry of FIG. 1 and the current controller circuitry 278 of FIGS. 2 and 3 may, thus, be instantiated at the same or different times. For example, same and/or different portion(s) of the microprocessor 1100 of FIG. 11 may be programmed to execute portion(s) of machine-readable instructions at the same and/or different times. In some examples, same and/or different portion(s) of the FPGA circuitry 1200 of FIG. 12 may be configured and/or structured to perform operations/functions corresponding to portion(s) of machine-readable instructions at the same and/or different times.

In some examples, some or all of the circuitry of FIG. 1 and the current controller circuitry 278 of FIGS. 2 and 3 may be instantiated, for example, in one or more threads executing concurrently and/or in series. For example, the microprocessor 1100 of FIG. 11 may execute machine-readable instructions in one or more threads executing concurrently and/or in series. In some examples, the FPGA circuitry 1200 of FIG. 12 may be configured and/or structured to carry out operations/functions concurrently and/or in series. Moreover, in some examples, some or all of the circuitry of FIG. 1 and the current controller circuitry 278 of FIGS. 2 and 3 may be implemented within one or more virtual machines and/or containers executing on the microprocessor 1100 of FIG. 11.

In some examples, the programmable circuitry 1012 of FIG. 10 may be in one or more packages. For example, the microprocessor 1100 of FIG. 11 and/or the FPGA circuitry 1200 of FIG. 12 may be in one or more packages. In some examples, an XPU may be implemented by the programmable circuitry 1012 of FIG. 10, which may be in one or more packages. For example, the XPU may include a CPU (e.g., the microprocessor 1100 of FIG. 11, the CPU 1220 of FIG. 12, etc.) in one package, a DSP (e.g., the DSP 1222 of FIG. 12) in another package, a GPU in yet another package, and an FPGA (e.g., the FPGA circuitry 1200 of FIG. 12) in still yet another package.

In this description, the term “and/or” (when used in a form such as A, B and/or C) refers to any combination or subset of A, B, C, such as: (a) A alone; (b) B alone; (c) C alone; (d) A with B; (e) A with C; (f) B with C; and (g) A with B and with C. Also, as used herein, the phrase “at least one of A or B” (or “at least one of A and B”) refers to implementations including any of: (a) at least one A; (b) at least one B; and (c) at least one A and at least one B.

In this description, the term “couple” may cover connections, communications, or signal paths that enable a functional relationship consistent with this description. For example, if device A generates a signal to control device B to perform an action: (a) in a first example, device A is coupled to device B by direct connection; or (b) in a second example, device A is coupled to device B through intervening component C if intervening component C does not alter the functional relationship between device A and device B, such that device B is controlled by device A via the control signal generated by device A.

Numerical identifiers such as “first”, “second”, “third”, etc. are used merely to distinguish between elements of substantially the same type in terms of structure and/or function. These identifiers as used in the detailed description do not necessarily align with those used in the claims.

A device that is “configured to” perform a task or function may be configured (e.g., programmed and/or hardwired) at a time of manufacturing by a manufacturer to perform the function and/or may be configurable (or re-configurable) by a user after manufacturing to perform the function and/or other additional or alternative functions. The configuring may be through firmware and/or software programming of the device, through a construction and/or layout of hardware components and interconnections of the device, or a combination thereof.

As used herein, the terms “terminal”, “node”, “interconnection”, “pin” and “lead” are used interchangeably. Unless specifically stated to the contrary, these terms are generally used to mean an interconnection between or a terminus of a device element, a circuit element, an integrated circuit, a device or other electronics or semiconductor component.

A circuit or device that is described herein as including certain components may instead be adapted to be coupled to those components to form the described circuitry or device. For example, a structure described as including one or more semiconductor elements (such as transistors), one or more passive elements (such as resistors, capacitors, and/or inductors), and/or one or more sources (such as voltage and/or current sources) may instead include only the semiconductor elements within a single physical device (e.g., a semiconductor die and/or integrated circuit (IC) package) and may be adapted to be coupled to at least some of the passive elements and/or the sources to form the described structure either at a time of manufacture or after a time of manufacture, for example, by an end-user and/or a third-party.

Circuits described herein are reconfigurable to include the replaced components to provide functionality at least partially similar to functionality available prior to the component replacement. Components shown as resistors, unless otherwise stated, are generally representative of any one or more elements coupled in series and/or parallel to provide an amount of impedance represented by the shown resistor. For example, a resistor or capacitor shown and described herein as a single component may instead be multiple resistors or capacitors, respectively, coupled in parallel between the same nodes. For example, a resistor or capacitor shown and described herein as a single component may instead be multiple resistors or capacitors, respectively, coupled in series between the same two nodes as the single resistor or capacitor. While certain elements of the described examples are included in an integrated circuit and other elements are external to the integrated circuit, in other example embodiments, additional or fewer features may be incorporated into the integrated circuit. In addition, some or all of the features illustrated as being external to the integrated circuit may be included in the integrated circuit and/or some features illustrated as being internal to the integrated circuit may be incorporated outside of the integrated. As used herein, the term “integrated circuit” means one or more circuits that are: (i) incorporated in/over a semiconductor substrate; (ii) incorporated in a single semiconductor package; (iii) incorporated into the same module; and/or (iv) incorporated in/on the same printed circuit board.

Uses of the phrase “ground” in the foregoing description include a chassis ground, an Earth ground, a floating ground, a virtual ground, a digital ground, a common ground, and/or any other form of ground connection applicable to, or suitable for, the teachings of this description. Unless otherwise stated, “about,” “approximately,” or “substantially” preceding a value means +/−10 percent of the stated value, or, if the value is zero, a reasonable range of values around zero.

Modifications are possible in the described embodiments, and other embodiments are possible, within the scope of the claims.

What is claimed is:

1. An apparatus comprising:
error detection circuitry having a terminal;
first controller circuitry including:
a first transistor having a first terminal and a control terminal, the control terminal of the first transistor coupled to the terminal of the error detection circuitry;
a second transistor having a first terminal and a control terminal;
first current source circuitry having a terminal; and
a third transistor having a control terminal coupled to the first terminal of the first transistor, the first terminal of the second transistor, the control terminal of the second transistor, and the terminal of the first current source circuitry; and
second controller circuitry including:
a fourth transistor having a first terminal and a control terminal, the control terminal of the fourth transistor coupled to the terminal of the error detection circuitry;
a fifth transistor having a first terminal and a control terminal;
a sixth transistor having a first terminal and a control terminal, the control terminal of the sixth transistor coupled to the first terminal of the fourth transistor, the first terminal of the fifth transistor, and the control terminal of the fifth transistor; and
second current source circuitry having a terminal coupled to the first terminal of the sixth transistor.

2. The apparatus of claim 1, wherein the error detection circuitry comprising:
resistor divider circuitry having a terminal; and
an error amplifier having a first terminal and a second terminal, the first terminal of the error amplifier coupled to the terminal of the resistor divider circuitry, the second terminal of the error amplifier coupled to the control terminal of the first transistor and the control terminal of the fourth transistor.

3. The apparatus of claim 1, further comprising first controller circuitry including:
third current source circuitry having a terminal;
a seventh transistor having a first terminal, a second terminal, and a control terminal, the first terminal of the seventh transistor coupled to the terminal of the third current source circuitry, the control terminal of the seventh transistor coupled to the control terminal of the first transistor and the control terminal of the fourth transistor; and
a resistor having a terminal coupled to the second terminal of the seventh transistor.

4. The apparatus of claim 1, wherein the second controller circuitry further including:
a seventh transistor having a first terminal and a control terminal; and
an eighth transistor having a control terminal coupled to the first terminal of the sixth transistor, the terminal of the second current source circuitry, the first terminal of the seventh transistor, and the control terminal of the seventh transistor.

5. The apparatus of claim 4, wherein the terminal of the error detection circuitry is a first terminal, the error detection circuitry further having a second terminal, the third transistor further having a first terminal, the eighth transistor further having a second terminal, the apparatus further comprising:
power stage circuitry having a first terminal, a second terminal, and a third terminal, the first terminal of the power stage circuitry coupled to the second terminal of the error detection circuitry;
first comparator circuitry having a first terminal and a second terminal, the first terminal of the first comparator circuitry coupled to the second terminal of the power stage circuitry, the second terminal of the first comparator circuitry coupled to the first terminal of the third transistor; and
second comparator circuitry having a first terminal and a second terminal, the first terminal of the second comparator circuitry coupled to the third terminal of the power stage circuitry, the second terminal of the second comparator circuitry coupled to the first terminal of the eighth transistor.

6. The apparatus of claim 5, further comprising:
logic circuitry having a first terminal, a second terminal, a third terminal, and a fourth terminal, the first terminal of the logic circuitry coupled to the first terminal of the first comparator circuitry, the second terminal of the logic circuitry coupled to the first terminal of the second comparator circuitry; and
driver circuitry having a first terminal, a second terminal, a third terminal, and a fourth terminal, the first terminal of the driver circuitry coupled to the third terminal of the logic circuitry, the second terminal of the driver circuitry coupled to the fourth terminal of the logic circuitry, the third terminal of the driver circuitry coupled to the second terminal of the power stage circuitry, the fourth terminal of the driver circuitry coupled to the third terminal of the power stage circuitry.

7. A system comprising:
power stage circuitry having a first input, a second input, and an output;
first comparator circuitry having an input and an output, the output of the first comparator circuitry configured to be coupled to the first input of the power stage circuitry;
second comparator circuitry having an input and an output, the output of the second comparator circuitry configured to be coupled to the second input of the power stage circuitry; and
peak-valley controller circuitry including:
error detection circuitry having an input, a first output, and a second output, the input of the error detection circuitry coupled to the output of the power stage circuitry;
peak controller circuitry having an input and an output, the input of the peak controller circuitry coupled to the first output of the error detection circuitry, the output of the peak controller circuitry coupled to the input of the first comparator circuitry; and
valley controller circuitry having an input and an output, the input of the valley controller circuitry coupled to the second output of the error detection circuitry, the output of the valley controller circuitry coupled to the input of the second comparator circuitry.

8. The system of claim 7, further comprising:
logic circuitry having a first input, a second input, a first output, and a second output, the first input of the logic circuitry coupled to the output of the first comparator circuitry, the second input of the logic circuitry coupled to the output of the second comparator circuitry; and
driver circuitry having a first input, a second input, a first output, and a second output, the first input of the driver circuitry coupled to the first output of the logic circuitry, the second input of the driver circuitry coupled to the second output of the logic circuitry, the first output of the driver circuitry coupled to the first input of the power stage circuitry, the second output of the driver circuitry coupled to the second input of the power stage circuitry.

9. The system of claim 7, wherein the error detection circuitry comprising:
resistor divider circuitry having a first terminal and a second terminal, the first terminal of the resistor divider circuitry coupled to the output of the power stage circuitry; and
an error amplifier having an input and an output, the input of the error amplifier coupled to the second terminal of the resistor divider circuitry, the output of the error amplifier configured to be coupled to the input of the peak controller circuitry and the input of the valley controller circuitry.

10. The system of claim 7, wherein the peak-valley controller circuitry further includes non-overlap calibration circuitry having an output coupled to the input of the peak controller circuitry and the input of the valley controller circuitry.

11. The system of claim 10, wherein the non-overlap calibration circuitry comprising:
current source circuitry having a terminal;
a transistor having a first terminal, a second terminal, and a control terminal, the first terminal of the transistor coupled to the terminal of the current source circuitry, the control terminal of the transistor coupled to the input of the peak controller circuitry and the input of the valley controller circuitry; and
a resistor having a terminal coupled to the second terminal of the transistor.

12. The system of claim 7, wherein the peak controller circuitry comprising:
a first transistor having a first terminal and a control terminal, the control terminal of the first transistor coupled to the first output of the error detection circuitry;
a second transistor having a first terminal and a control terminal, the first terminal of the second transistor coupled to the first terminal of the first transistor and the control terminal of the second transistor;
current source circuitry having a terminal coupled to the first terminal of the first transistor, the first terminal of the second transistor, and the control terminal of the first transistor; and
a third transistor having a first terminal and a control terminal, the first terminal of the third transistor coupled to the input of the first comparator circuitry, the control terminal of the third transistor coupled to the first terminal of the first transistor, the first terminal of the second transistor, the control terminal of the second transistor, and the terminal of the current source circuitry.

13. The system of claim 7, wherein the valley controller circuitry comprising:
a first transistor having a first terminal and a control terminal, the control terminal of the first transistor coupled to the second output of the error detection circuitry;
a second transistor having a first terminal and a control terminal;
a third transistor having a first terminal and a control terminal, the control terminal of the third transistor coupled to the first terminal of the first transistor, the first terminal of the second transistor, and the control terminal of the second transistor;
current source circuitry having a terminal;
a fourth transistor having a first terminal and a control terminal; and
a fifth transistor having a first terminal, and a control terminal, the first terminal of the fifth transistor coupled to the input of the second comparator circuitry, the control terminal of the fifth transistor coupled to the first terminal of the third transistor, the terminal of the current source circuitry, the first terminal of the fourth transistor, and the control terminal of the fourth transistor.

14. An apparatus comprising:
error detection circuitry having an input and an output, the error detection circuitry configured to integrate a difference between a voltage of the input of the error detection circuitry and a reference voltage to produce an integrated error voltage;
peak controller circuitry coupled to the error detection circuitry, the peak controller circuitry to compare a control current to a first reference current to generate a peak control current, the control current based on an integrated error voltage, the peak control current to increase an output current of converter circuitry; and
valley controller circuitry coupled to the error detection circuitry and the peak controller circuitry, the valley controller circuitry to compare the control current to a second reference current to generate a valley control current, the valley control current to decrease the output current of the converter circuitry.

15. The apparatus of claim 14, wherein the error detection circuitry further configured to:
multiply the voltage of the input of the error detection circuitry by an attenuation value to produce an attenuated output voltage; and
compare the attenuated output voltage to the reference voltage to determine an error of an output voltage of the converter circuitry.

16. The apparatus of claim 14, wherein the peak controller circuitry is further configured to control a transistor of the peak controller circuitry using the integrated error voltage to generate the control current.

17. The apparatus of claim 14, wherein the peak controller circuitry is further configured to:
responsive to the control current being greater than the first reference current, set the peak control current approximately equal to the control current minus the first reference current; and
responsive to the control current being less than the first reference current, set the peak control current approximately equal to zero.

18. The apparatus of claim 14, wherein the valley controller circuitry is further configured to:
responsive to the control current being greater than the second reference current, set the valley control current approximately equal to zero; and
responsive to the control current being less than the second reference current, set the valley control current approximately equal to the second reference current minus the control current.

19. The apparatus of claim 14, further comprising non-overlap calibration circuitry coupled to the peak controller circuitry and the valley controller circuitry, the non-overlap calibration circuitry configured to trim the first reference current of the peak controller circuitry based on the peak control current and the valley control current.

20. The apparatus of claim 19, wherein the non-overlap calibration circuitry further configured to:
determine a first zero crossing current of the valley control current;
determine a second zero crossing current of the peak control current at a first current;
adjust the first reference current from the first current to a second current;
determine a third zero crossing current of the peak control current at the second current; and
select one of the first current or the second current based on the first zero crossing, the second zero crossing, and the third zero crossing.
